(19) United States
(12) Patent Application Publication
(10) Pub. No.: US 2018/0031602 A1
(43) Pub. Date: Feb. 1, 2018

(54) CONVERTING ROTATIONAL MOTION TO LINEAR MOTION

(71) Applicant: Lumedyne Technologies Incorporated, San Diego, CA (US)

(72) Inventors: Xiaojun Huang, San Diego, CA (US); Ozan Anac, Oakland, CA (US); Richard Lee Waters, San Diego, CA (US)

(21) Appl. No.: 15/221,566

(22) Filed: Jul. 27, 2016

(51) Int. Cl. G01P 15/13; G01C 19/5719

(52) U.S. Cl. CPC G01P 15/13; G01C 19/5719; B81C 1/00246

(57) ABSTRACT

System and methods are disclosed herein for converting rotational motion to linear motion. A system comprising a rotational drive can be connected to a proof mass by a first structure comprising a coupling spring. An anchor can be connected to the proof mass by a second structure comprising a drive spring. The coupling spring and the drive spring can be configured to cause the proof mass to move substantially along a first axis when the rotational drive rotates about a second axis.

### BACKGROUND

Monolithic inertial sensors can contain proof masses that move in response to inertial perturbations such as accelerations and rotations. Some inertial sensors contain proof masses that are driven in oscillation. A linear drive can drive a proof mass in linear oscillation, and a rotational drive can drive a proof mass in rotational oscillation. For proof masses that are driven in linear oscillation, any component of motion that is not aligned with the primary axis of measurement can reduce the signal-to-noise level of the sensor.

### SUMMARY

Accordingly, systems and methods are described herein for converting rotational motion to linear motion. A system can include a proof mass, a rotational drive configured to rotate about a z axis, and a first structure that connects the rotational drive to the proof mass. The first structure can include a major axis that passes from a first anchor to the proof mass and is aligned with a y axis when the first structure is at rest, the y axis perpendicular to the z axis, and a coupling spring with a stiffness along a minor axis perpendicular to the major axis that is different than a stiffness along the major axis. The system can include a second structure including a drive spring with a stiffness along the y axis that is different than a stiffness along an x axis perpendicular to the y and z axes. The system can also include a second anchor connected to the proof mass by the second structure.

The coupling spring and the drive spring can be configured to cause the proof mass to move substantially along the x axis when the rotational drive rotates about the z axis. The coupling spring can be configured to bend when the rotational drive rotates.

A center of mass of the proof mass can be radially between a point at which the drive spring is attached to the proof mass and a point at which the coupling spring is attached to the proof mass. The drive spring can exert, on the proof mass, a torque that substantially prevents rotation of the proof mass about the center of mass.

The first structure can include an arm. The stiffness of the coupling spring along the minor axis can be substantially greater than the stiffness of the coupling spring along the major axis. The stiffness of the drive spring along the y axis can be substantially greater than the stiffness of the drive spring along the x axis.

The system can include a second drive spring connected to the proof mass and a third anchor, the second drive spring with a stiffness along the y axis that is different than a stiffness along an x axis.

The drive spring can be configured to expand when the rotational drive rotates about the z axis with a first rotation vector and compress when the rotational drive rotates about the z axis with a second rotation vector opposite to the first rotation vector.

The first structure can include a drive frame. The stiffness of the coupling spring along the major axis can be substantially greater than the stiffness of the coupling spring along the minor axis. The stiffness of the drive spring along the y axis can be substantially greater than the stiffness of the drive spring along the x axis.

The proof mass can include a sensor configured to characterize the motion of the proof mass along the x axis. The sensor can include a comb and/or a time-domain-switched structure. The sensor can be configured to determine an acceleration of the system along the x axis, and/or a velocity of the proof mass along the x axis.

The system can include a second proof mass connected to the rotational drive by a third structure including a second coupling spring and a third anchor connected to the second proof mass by a fourth structure including a second drive spring. The second coupling spring and the second drive spring can be configured to cause the second proof mass to move substantially along the y axis when the rotational drive rotates about the z axis.

The coupling spring can include a first coupling joint connected to an end of the arm, first and second flex arms connected to the first coupling joint, and first and second forks connected to the first and second flex arms, respectively. The system can include third and fourth flex arms connected to the first and second forks, respectively, and a second coupling joint connected to the third and fourth flex arms and to the proof mass.

The drive spring can include an anchor fork connected to the second anchor, an anchor arm connected to the anchor fork, and a first drive fork connected to the anchor arm. The drive spring can also include a drive arm connected to the first drive fork, and a second drive fork connected to the drive arm and to the proof mass.

The second drive spring can include a second anchor fork connected to the third anchor, a second anchor arm connected to the second anchor fork, and a third drive fork connected to the second anchor arm. The second drive spring can also include a second drive arm connected to the third drive fork, and a fourth drive fork connected to the second drive arm and to the proof mass.

The coupling spring can include a driving fork connected to the drive frame, first and second driving arms connected to the driving fork, and first and second middle forks connected to the first and second driving arms, respectively. The coupling spring can also include first and second middle arms connected to the first and second middle forks, respectively, and a first driven fork connected to the first and second middle arms. The coupling spring can also include a driven arm connected to the first driven fork and a second driven fork connected to the driven arm and to the proof mass.

The coupling spring can include a first coupling joint connected to the drive frame, first and second flex arms connected to the first coupling joint, and first and second forks connected to the first and second flex arms, respectively. The coupling spring can also include third and fourth flex arms connected to the first and second forks, respectively, and a second coupling joint connected to the third and fourth flex arms and to the proof mass.

The drive spring can also include an anchor fork connected to the second anchor, an anchor arm connected to the anchor fork, and a first drive fork connected to the anchor arm. The drive spring can also include a drive arm connected to the first drive fork and a second drive fork connected to the drive arm and to the proof mass.

The system can also include a second proof mass connected to the rotational drive by a third structure including a second coupling spring and a third anchor connected to the second proof mass by a fourth structure including a second drive spring. The second coupling spring and the second drive spring can be configured to cause the second proof mass to move substantially along the third axis when the rotational drive rotates about the second axis.

The system can include a third proof mass connected to the rotational drive by a fifth structure including a third coupling spring and a fourth anchor connected to the third proof mass by a sixth structure including a third drive spring. The third coupling spring and the third drive spring can be configured to cause the third proof mass to move substantially along the first axis when the rotational drive rotates about the second axis.

The system can include a fourth proof mass connected to the rotational drive by a seventh structure including a fourth coupling spring and a fifth anchor connected to the fourth proof mass by an eighth structure including a fourth drive spring. The fourth coupling spring and the fourth drive spring can be configured to cause the fourth proof mass to move substantially along the third axis when the rotational drive rotates about the second axis.

The system can include a fifth proof mass connected to the rotational drive by a ninth structure including a fifth coupling spring and a sixth anchor connected to the fifth proof mass by a tenth structure including a fifth drive spring. The fifth coupling spring and the fifth drive spring can be configured to cause the fifth proof mass to move substantially along a fourth axis when the rotational drive rotates about the second axis, the fourth axis perpendicular to the second axis.

The system can include a sixth proof mass connected to the rotational drive by a eleventh structure including a sixth coupling spring and a seventh anchor connected to the sixth proof mass by a twelfth structure including a sixth drive spring. The sixth coupling spring and the sixth drive spring can be configured to cause the sixth proof mass to move substantially along the fourth axis when the rotational drive rotates about the second axis.

The system can include a seventh proof mass connected to the rotational drive by a thirteenth structure including a seventh coupling spring and a eighth anchor connected to the seventh proof mass by a fourteenth structure including a seventh drive spring. The system can also include an eighth proof mass connected to the rotational drive by a fifteenth structure including an eighth coupling spring and a ninth anchor connected to the eighth proof mass by a sixteenth structure including an eighth drive spring. The seventh coupling spring and the seventh drive spring can be configured to cause the seventh proof mass to move substantially along a fifth axis when the rotational drive rotates about the second axis, the fifth axis perpendicular to the second and fourth axes. Furthermore, the eighth coupling spring and the eighth drive spring can be configured to cause the eighth proof mass to move substantially along the fifth axis when the rotational drive rotates about the second axis.

### BRIEF DESCRIPTION OF THE DRAWINGS

FIG. 1 depicts an inertial sensor comprising spring systems that convert rotational motion to linear motion, according to an illustrative implementation;

FIG. 2 depicts an enlarged view of an area of interest depicted in FIG. 1, with a time-domain-switched subassembly displaced in a clockwise direction from its neutral position, according to an illustrative implementation;

FIG. 3 depicts the inertial sensor shown in FIG. 1 when a drive comb has rotated the arm counterclockwise from its neutral position, according to an illustrative implementation;

FIG. 4 depicts an enlarged view of a coupling spring, according to an illustrative implementation;

FIG. 5 depicts the coupling spring shown in FIG. 4 when an arm is rotated clockwise from its neutral position, according to an illustrative implementation;

FIG. 6 depicts an inertial sensor with springs that convert rotational motion to linear motion, according to an illustrative implementation;

FIG. 7 depicts an enlarged view of an area of interest shown in FIG. 6, according to an illustrative implementation;

FIG. 8 depicts the inertial sensor shown in FIG. 6 when drive combs have caused a drive frame to rotate counterclockwise about the z-axis of the inertial sensor, according to an illustrative implementation;

FIG. 9 depicts an enlarged view of a drive spring when drive combs have rotated the drive frame counterclockwise about the z-axis, according to an illustrative implementation;

FIG. 10 depicts the drive spring shown in FIG. 9 when the drive combs have rotated the drive frame clockwise about the z-axis from its neutral position, according to an illustrative implementation;

FIG. 11 depicts a coupling spring of the inertial sensor shown in FIG. 6 when the drive combs have rotated the drive frame counterclockwise about the z-axis, according to an illustrative implementation;

FIG. 12 depicts the coupling spring shown in FIG. 11 when the drive combs have rotated the drive frame clockwise about the z-axis from its neutral position, according to an illustrative implementation;

FIG. 13 depicts an inertial sensor with springs that convert rotational motion to linear motion, according to an illustrative implementation;

FIG. 14 depicts the inertial sensor shown in FIG. 13 when drive combs have rotated a drive frame counterclockwise about the z-axis of the inertial sensor from its neutral position, according to an illustrative implementation;

FIG. 15 depicts an enlarged view of a gyroscope subassembly of the inertial sensor shown in FIG. 13 when a drive frame is in its neutral position, according to an illustrative implementation;

FIG. 16 depicts a view of the gyroscope subassembly shown in FIG. 15 when the drive combs have rotated the drive frame counterclockwise about the z-axis of the inertial sensor from its neutral position, according to an illustrative implementation;

FIG. 17 depicts three views, each showing a schematic representation of parts of a movable element and a fixed element, according to an illustrative implementation;

FIG. 18 schematically depicts an exemplary process used to extract inertial information from an inertial sensor with periodic geometry, according to an illustrative implementation;

FIG. 19 depicts a graph which represents the association of analog signals derived from an inertial sensor with zero-crossing times and displacements of an inertial sensor, according to an illustrative implementation;

FIG. 20 depicts a graph showing effects of an external perturbation on input and output signals of an inertial sensor, according to an illustrative implementation;

FIG. 21 depicts a graph that illustrates a response in the form of an electrical current to an oscillator displacement, according to an illustrative implementation;

FIG. 22 depicts a graph showing a rectangular waveform and signal representing zero-crossing times of the current signal depicted in FIG. 21, according to an illustrative implementation;

FIG. 23 is a graph which illustrates additional time intervals of the displacement curve depicted in FIG. 21, according to an illustrative implementation;

FIG. 24 is a graph that depicts the relationship between capacitance of the inertial sensor depicted in FIG. 18 and displacement of the movable element depicted in FIG. 17, according to an illustrative implementation;

FIG. 25 is a graph that depicts the relationship between displacement and the first derivative of capacitance with respect to displacement, according to an illustrative implementation;

FIG. 26 is a graph that depicts the relationship between displacement and the second derivative of capacitance with respect to displacement, according to an illustrative implementation; and

FIG. 27 is a graph that depicts the relationship between time, the rate of change of capacitive current, and displacement, according to an illustrative implementation.

FIG. 28 depicts a flow chart of a method used to extract inertial parameters from a nonlinear periodic signal, according to an illustrative implementation;

FIG. 29 depicts a method for determining times of transition between two values based on nonlinear periodic signals, according to an illustrative implementation; and

FIG. 30 depicts a method to compute inertial parameters from time intervals, according to an illustrative implementation.

### DETAILED DESCRIPTION

To provide an overall understanding of the disclosure, certain illustrative implementations will now be described, including systems and methods for converting rotational motion to linear motion.

When a vertically-oriented lever is rotated about a pivot point, the end of the lever distal from the pivot point traces an arc: it moves in a circumferential direction. As the distal end of the lever traces the arc, the distal end moves horizontally and also in the vertical direction. The spring mechanisms described herein substantially remove this vertical component of motion, converting rotational motion to linear motion.

Some types of sensors, such as vibratory accelerometers and Coriolis force vibrating gyroscopes, require a proof mass to be oscillated linearly along an axis. Inertial parameters such as accelerations and rotations can affect the oscillating proof mass. In some examples, such as vibratory accelerometers, the oscillations become offset from the neutral point due to an acceleration. To sense inertial parameters acting along multiple axes, an inertial sensing apparatus requires proof masses that oscillate along multiple axes. The systems and methods described herein integrate multiple sensors with proof masses oscillating along different axes into a single multi-axis device driven by a single rotational drive. This allows the motion of each of the proof masses to be synchronized in frequency, phase, and amplitude.

The systems and methods described herein may integrate multiple sensors with proof masses into a single multi-axis device by converting rotational motion to linear motion, allowing inertial sensors requiring linear proof mass motion to be driven by a rotational drive. The frequency and phase of the inertial sensors are synchronized because the same drive system actuates each of the inertial sensors.

By placing the inertial sensors at appropriate azimuthal positions on the rotational drive, sensors moving in orthogonally linear directions can be realized. The amplitude of each of the inertial sensors is controlled by its distance from the pivot point of the rotational drive. Because all of the inertial sensors are driven by the same drive, any drifting in the drive electronics will affect the frequency, phase, and amplitudes of the inertial sensors in the same manner. Likewise, drift due to other factors such as temperature, mechanical stress, or external forces will also affect all of the inertial sensors in the same manner. Because the inertial sensors are located relatively close to each other on the same drive frame, mechanical stresses such as packaging stress which deform the overall package of the inertial sensor, will tend to cause little relative motion between various parts of the inertial sensor. Thus, the ratio of the drive amplitude of one inertial sensor to the drive amplitude of another inertial sensor is determined by the geometry of the inertial device as fabricated and are not typically changed by any other factors. This results in an inertial device with sensors that have very stable amplitude ratios, and essentially the same frequency and phase. Thus, the inertial sensors of the inertial device are mechanically synchronized in frequency, phase, and amplitude ratio.

The power consumed by drive electronics is often the largest fraction of total power consumed by an oscillating inertial device. The energy required to power the drive electronics is often significantly more than the kinetic energy required to oscillate the resonators. Thus, driving multiple inertial sensors with a single oscillating drive reduces the overall power consumption by reducing the number of systems of drive electronics. Furthermore, oscillating inertial sensors often do not oscillate continuously, but only oscillate when their output is required. This may occur when, for example, a user begins using a navigation or virtual reality application of a mobile device that requires inertial sensing. Thus, oscillating resonators are required to start and stop frequently. Starting an oscillating resonator requires adjusting a drive voltage of the resonator in a closed-loop fashion until the amplitude of the oscillations increases to a desired setpoint. Start up times of oscillating inertial devices can range from 10 milliseconds to multiple seconds, depending on the quality factor of the resonators and on other factors. When multiple sensors are driven by a single rotational drive, they can be started and stopped in unison.

Springs in the inertial devices may have certain configurations. In some examples, the tailored stiffness and compliance of springs described herein is achieved purely by the geometry of the springs. In some examples, the springs comprise a uniform isotropic material, such as doped or undoped silicon. In other examples, the material properties of the springs are tailored in various portions of the spring to achieve desired variations in stiffness and compliance.

Driving a proof mass with a rotational drive can result in more nonlinearity in the motion of the proof mass due to the rotation. The spring systems described herein can substantially linearize the motion of the proof mass of the inertial sensors by controlling and minimizing off-axis motion. The spring systems can achieve this goal by including springs with higher stiffness in off-axis directions, and/or by counterbalancing with springs that convert parasitic off-axis motion into motion in on-axis directions. In some examples, the remaining off-axis (rotational) component of the motion of the proof mass is 100 PPM of the on-axis (linear) component. In some examples, the off-axis (rotational) component is as low as 10 PPM or as high as 1000 PPM of the on-axis (linear) component. Thus, for a proof mass on a vertically-oriented arm and rotating about the origin and having an oscillation in the x direction of 1 micron, the proof mass only moves in the y direction by 1 nanometer (corresponding to 1000 PPM), 0.1 nanometers (corresponding to 100 PPM) or as little as 0.01 nanometers (corresponding to 10 PPM).

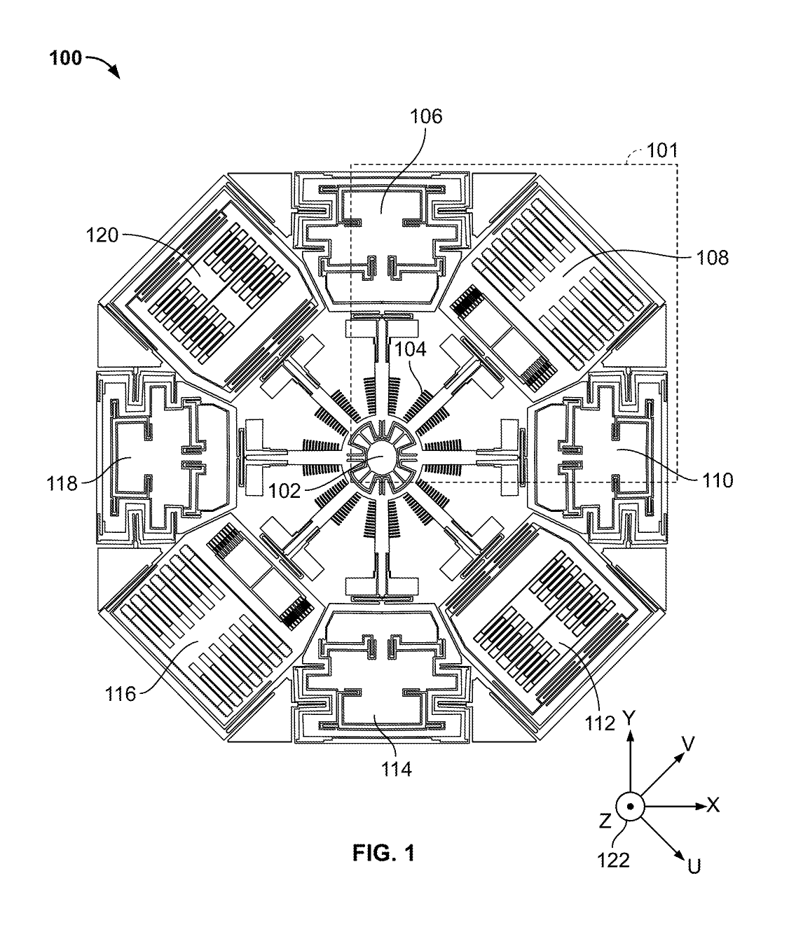

FIG. 1 depicts an inertial sensor 100 comprising spring systems that convert rotational motion to linear motion. The inertial sensor 100 includes a central anchor 102 and a drive comb 104. The drive comb 104 is an example of a rotational drive. FIG. 1 only depicts movable portions of the drive comb 104, but the drive comb 104 also includes fixed portions that are not shown. The inertial sensor 100 also includes six gyroscope subassemblies 106, 110, 112, 114, 118, and 120. In addition, the inertial sensor 100 includes time-domain-switched (TDS) subassemblies 108 and 116. FIG. 1 also depicts a coordinate system 122 with an x-y-z coordinate system sharing a z-axis and an origin with a u-v-z coordinate system. While the coordinate system 122 is depicted offset from the inertial sensor 100 for clarity, the origin of the coordinate system 122 is located at the center of the central anchor 102. The x- and y-axes are orthogonal to each other. The u- and v-axes are orthogonal to each other and are rotated by −45 degrees from the x- and y-axes, respectively. FIG. 1 also depicts an area of interest 101.

The inertial sensor 100 comprises three layers, a device layer containing the features depicted in FIG. 1, a bottom layer (not shown), and a cap layer (not shown). In some examples, the bottom layer and cap layer are made from different wafers than the device layer. In some examples, one or more features of the device layer can be made from the wafers containing the bottom layer and/or the cap layer. The region between the bottom and cap layers can be at a pressure below atmospheric pressure. In some examples, a gettering material such as titanium or aluminum is deposited to maintain the reduced pressure for an extended period of time after manufacturing the inertial sensor.

The central anchor 102 is anchored to one or both of the bottom and cap layers and is the central pivot point of the inertial sensor 100. The drive comb 104 causes the respective subassemblies to rotationally oscillate about the central anchor 102. This oscillation causes the gyroscope subassemblies 106, 110, 114, and 118 to move at a drive velocity. When the inertial sensor 100 is rotated, a Coriolis force proportional to the rotation rate causes proof masses of the gyroscope subassemblies 106, 110, 114, and 118 to deflect.

The gyroscope subassemblies 106, 110, 114, and 118 provide differential sensing for rotation about the x- and y-axes. Here, and throughout, rotations, accelerations, displacements, and other parameters described with reference to the x- and y-axes can be mathematically transformed to reference the u- and v-axes instead, and vice versa, by a simple rotation of the relevant coordinate system. This transformation can be performed by signal processing circuitry. Capacitor electrodes (not shown) are located either above or below a respective proof mass of each of the gyroscope subassemblies 106, 110, 114, and 118. The capacitor electrodes can be located in a cap layer and/or a bottom layer. These capacitor electrodes detect motion of the respective proof masses in the z direction in response to a rotation about the x-axis, the y-axis, or another axis in the x-y plane. The gyroscope subassemblies 112 and 120 contain proof masses that deflect radially in response to rotations about the z-axis.

The TDS subassemblies 108 and 116 can be used to measure drive velocity, acceleration along the u-axis, or both. For either measurement, accuracy is improved if the subassembly 108 and/or 116 oscillates purely along the u-axis. The systems and methods described herein convert the rotational motion imparted by the drive comb 104 into linear motion along the u-axis.

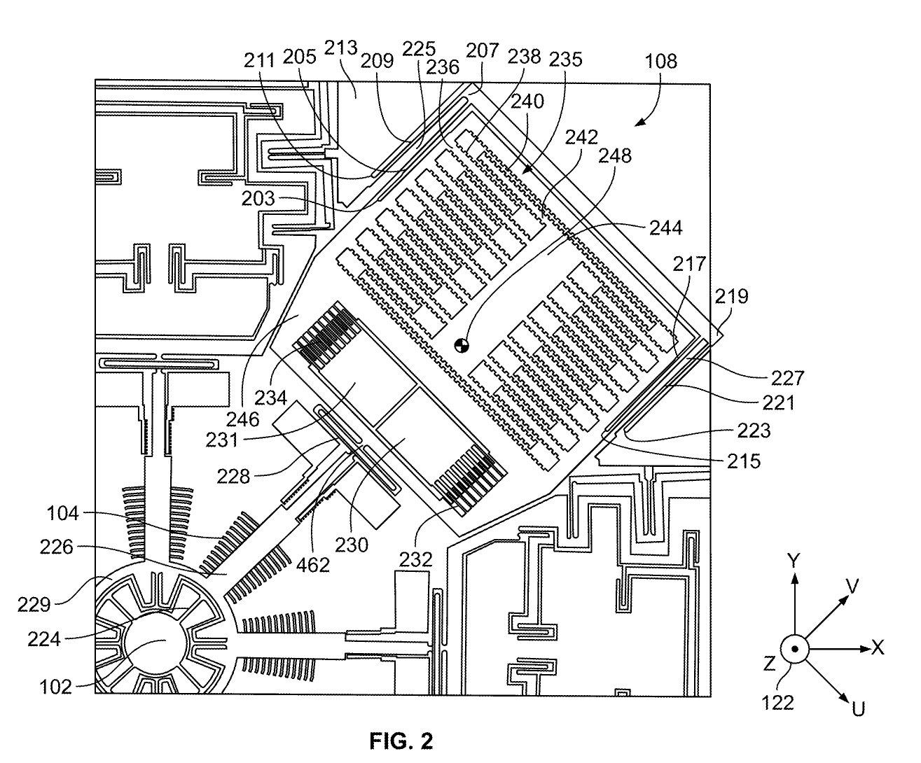

In some examples, the inertial sensor 100 does not contain a TDS structure, such as the TDS structure 235 of the TDS subassembly 108 which is further described with reference to FIG. 2, but instead uses one or more drive sense combs for both velocity measurement and drive comb regulation. In some examples, the inertial sensor 100 does not include drive sense combs and uses the TDS structure (e.g., 235) for both velocity measurement and drive comb regulation. In some examples, the inertial sensor 100 contains both TDS structures (e.g., 235) and drive sense combs and uses the TDS structure (e.g., 235) for drive comb regulation and the drive sense combs for velocity measurement. In some examples, the inertial sensor 100 uses the TDS structure (e.g., 235) for velocity measurement and the drive sense combs for drive comb regulation.

FIG. 2 depicts an enlarged view of the area of interest 101 from FIG. 1, with a proof mass 246 of the TDS subassembly 108 displaced in the clockwise direction from its neutral position. The proof mass 246 has a center of mass 248. The center of mass 248 is the point at which the mass-weighted position vectors of each portion of the proof mass 246 sum to zero. The center of mass of an object is not necessarily located on or within the object, and in FIG. 2 the center of mass 248 is indeed not located within the proof mass 246.

FIG. 2 also depicts a rotational spring 224 and an arm 226. The rotational spring 224 comprises a plurality of proximal ends and a plurality of distal ends. The proximal ends are connected to the anchor point and the distal ends are connected to a circular frame 229. The arm 226, as well as a plurality of other arms, comprises a proximal end and a distal end. The arm 226 has a major axis running along its length and a minor axis that is perpendicular to the major axis and in the u-v plane. When the arm is at rest, the major axis is aligned with the v axis and the minor axis is aligned with the u axis. The u axis is perpendicular to the z and v axes. The proximal end of the arm 226 is connected to the circular frame 229. The rotational spring 224 allows the circular frame and the arms to rotate about the z-axis, located at the center of the central anchor 102. As the arm 226 rotates about the z-axis, the distal end of the arm 226 travels in an arc. Without any of the spring systems described herein, the proof mass 246 would also travel in an arc and thus would have both u and v components of motion. However, one or more of the spring systems described herein substantially eliminate the v component of motion, resulting in proof mass 246 moving almost entirely along the u-axis in response to rotation caused by the drive comb 104.

The distal end of the arm 226 is connected to a coupling spring 228. The coupling spring 228 transmits circumferential motion (that is, motion perpendicular to the long axis of the arm 226) to the proof mass 246 through a coupling joint 462. Because the coupling spring 228 has an open center, the coupling spring 228 is compliant in the radial direction (that is, the direction parallel to the long axis of the arm 226). Because the coupling spring 228 is rigid in the circumferential direction but compliant in the radial direction, the proof mass 246 moves with the arm 226, but the gap between the proof mass 246 and the distal end of the arm 226 can vary.

The coupling spring 228 works in tandem with a pair of drive springs 225 and 227 to convert rotational motion to linear motion of the proof mass 246. The drive spring 225 comprises an anchor fork 211, an anchor arm 209, a drive fork 207, a drive arm 205, and a drive fork 203. The anchor arm 209 is connected to an anchor 213 at the anchor fork 211. The anchor 213 is anchored to the bottom layer and/or the cap layer and is not moved by the drive comb 104. The drive arm 205 is connected to the anchor arm 209 at the drive fork 207. The drive arm 205 is connected to the proof mass 246 at the drive fork 203. The anchor arm 209 and the drive arm 205 are compliant in the u direction but rigid in the v direction. Thus, while the distance along the u-axis between the anchor fork 211 and the drive fork 203 can vary, the distance along the v-axis between the two forks does not vary.

The structure of the drive spring 227 is a mirror image of the structure of the drive spring 225 and comprises a drive fork 215, a drive arm 217, an drive fork 219, an anchor arm 221, and an anchor fork 223. The drive spring 227 is compliant in the u direction but rigid in the v direction. Thus, the drive fork 215 and the anchor fork 223 can move relative to each other in the u direction but cannot do so in the v direction. The drive arms 205 and 217 and the anchor arms 209 and 221 are compliant in the u direction but stiff in the v and z directions because their dimensions in u are much smaller than their dimensions in v and z. Because the drive springs 225 and 227 are not perfect springs, they are not perfectly rigid and thus have finite stiffnesses. Thus, the drive springs 225 and 227 do allow some motion of the proof mass 246 in the u direction. However, although the drive springs 225 and 227 are compliant in the u direction, they are stiff in the v direction such that motion of the proof mass 246 in the v direction is small. Thus, the coupling spring 228 and the drive springs 225 and 227 convert rotational motion about the z axis into linear motion of the proof mass 246 substantially along the u axis.

The spring systems described herein (e.g., the drive springs 225 and 227 and the coupling spring 228) can also convert rotational motion to linear motion through dynamic effects. The dynamic effects occur because the center of mass 248 is located at a different radius from the central anchor 102 than the points at which the drive springs are connected to the proof mass 246. For the TDS subassembly 108, the drive springs 225 and 227 are attached to the proof mass 246 at the drive forks 203 and 215. The drive comb 104 exerts, on the arm 226 and coupling spring 228, a torque about the central anchor 102. The coupling spring 228 then exerts a force on the proof mass 246 that is in the +u direction and acting through the coupling joint 462. This force can be resolved into a resolved torque about the center of mass 248 and a resolved force acting through the center of mass 248. Thus, if the drive comb 104 is exerting a clockwise torque, and the arm 226 is rotating clockwise about the central anchor 102, the resolved torque be counterclockwise and will tend to rotate the proof mass 246 counterclockwise about the center of mass 248. The radius of the center of mass 248 is greater than the radius of the coupling joint 462 and less than the respective radii of the drive forks 203 and 215 (where the radii are measured with respect to the central anchor 102). However, because the center of mass 248 is radially between the coupling joint 462 and the drive forks 203 and 215, the drive forks 203 and 215 exert a counter-torque that is clockwise about the center of mass 248.

This counter-torque tends to rotate the proof mass 246 clockwise about the center of mass 248, thus counteracting the tendency of the resolved torque to rotate the proof mass 246 counterclockwise about the center of mass 248. The directions of the resolved torque and the counter-torque would be reversed for counterclockwise torques exerted on the arm 226 by the drive comb 104. The properties of the TDS subassembly 108 can affect the magnitudes of the resolved torque and the counter-torque. Some properties that affect these magnitudes include the mass of the proof mass 246, the location of the center of mass 248 (especially the radial distance from the central anchor 102), the locations of the drive forks 203 and 215 (especially the radial distances from the central anchor 102), the stiffnesses of the drive springs 225 and 227 and the coupling spring 228, and the location of the coupling spring 228. By choosing these and other properties such that the counter-torque mostly or fully counteracts the resolved torque, the counter-torque substantially prevents rotation of the proof mass 246 about the center of mass 248. Thus, rotational motion about the z axis is converted into motion of the proof mass 246 substantially along the u axis.

FIG. 2 depicts the area of interest 101 (FIG. 1) of inertial sensor 100 (FIG. 1) when the drive comb 104 has rotated the arm 226 in the counterclockwise direction from its neutral position. The coupling spring 228 has transmitted the u component of this rotation to the proof mass 246. The drive springs 225 and 227 have allowed the proof mass 246 to move in the +u direction while preventing it from moving in the v direction. Because the drive springs 225 and 227 have prevented the proof mass 246 from moving in the v direction, the distance between the proof mass 246 and the distal end of the arm 226 has increased. Because the coupling spring 228 is compliant in the v direction, the distance between the proof mass 246 and the distal end of the arm 226 can change while motion in the u direction is still transmitted. Thus, the coupling spring 228 and the drive springs 225 and 227 have converted the rotational motion of the arm 226 into linear motion of the proof mass 246.

FIG. 2 also depicts anchors 230 and 231 and comb sensors 232 and 234. The anchors 230 and 231 are anchored to the bottom layer and/or the cap layer and do not move relative to the central anchor 102. The comb sensors 232 and 234 experience a change in capacitance when the proof mass 246 moves in the u direction. The comb sensors 232 and 234 can characterize the motion of the proof mass 246 along the u axis. In some examples, the outputs from the comb sensors 232 and 234 are used to determine the velocity of the proof mass 246 in the u direction. In other examples, the outputs from the comb sensors 232 and 234 are used to regulate the velocity at which the arm 226 is oscillated by the drive comb 104. In other examples, the output of one of the comb sensors 232 and 234 is used to regulate the drive comb 104 in closed-loop feedback and the output of the other of the comb sensors 232 and 234 is used to determine the velocity in the u direction of the proof mass 246.

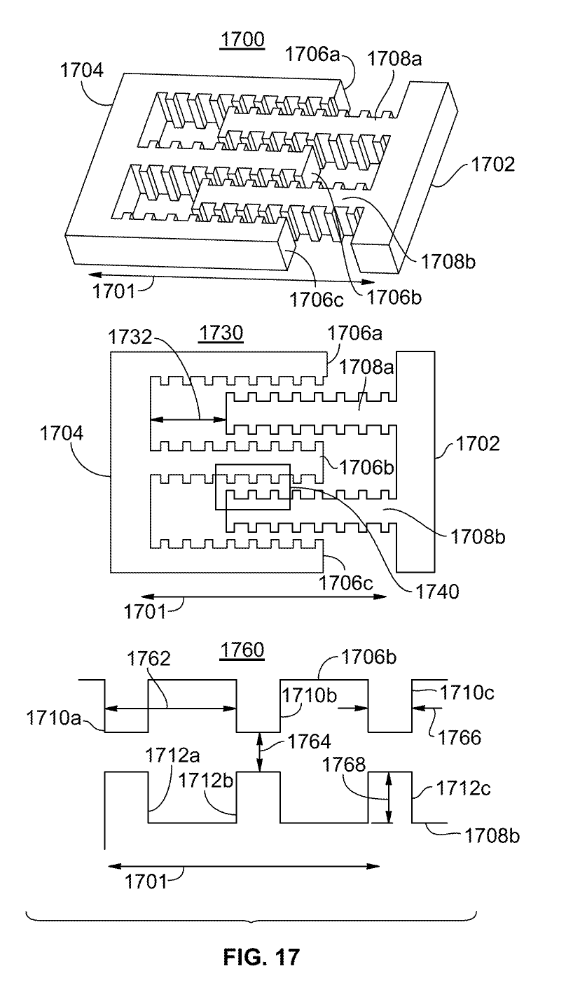

The TDS subassembly 108 includes a TDS structure 235 configured to characterize motion of the proof mass 246 in the u direction. The TDS structure 235 includes a movable beam 236 comprising a plurality of equally spaced teeth 238. The TDS structure 235 also includes a fixed element 244 comprising a fixed beam 242, itself comprising a plurality of teeth 240. The fixed element 244 is anchored to the bottom layer and/or the cap layer and does not move relative to the central anchor 102. The TDS structure 235 can produce nonlinear capacitive signals for determining velocity in the u direction of the proof mass 246, an offset in oscillations along the u direction of the proof mass 246, or both. The systems and methods described with reference to FIGS. 17-30 can be used to determine this velocity and offset. The offset in the oscillations is proportional to an acceleration acting on the inertial sensor 100 in the u direction.

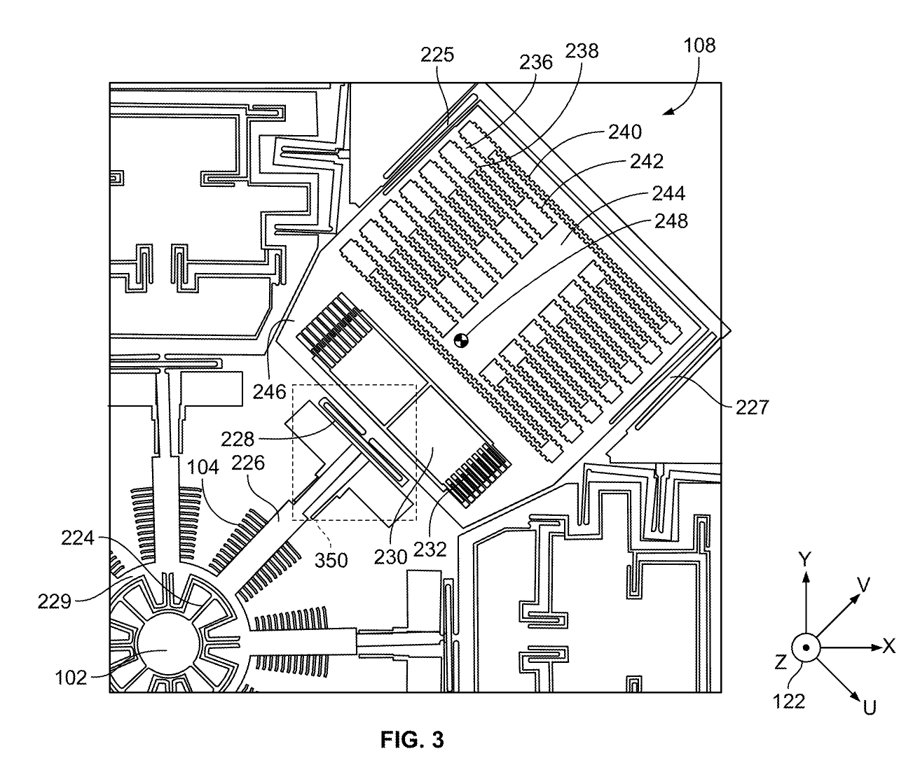

FIG. 3 depicts the area of interest 101 (FIG. 1) of inertial sensor 100 (FIG. 1) when the drive comb 104 has rotated the arm 226 counterclockwise from its neutral position. The coupling spring 228 has transmitted motion in the −u direction to the proof mass 246. The drive springs 225 and 227 have allowed the proof mass 246 to move in the −u direction while preventing it from moving in the v direction. The drive spring 225 compresses slightly while the drive spring 227 expands slightly. Because the proof mass 246 does not move in the v direction, the coupling spring 228 expands slightly in the v direction to allow the v distance between the proof mass 246 and the distal end of the arm 226 to vary. Thus, the coupling spring 228 and the drive springs 225 and 227 have converted the rotational motion of the arm 226 into linear motion of the proof mass 246. FIG. 3 also depicts an area of interest 350.

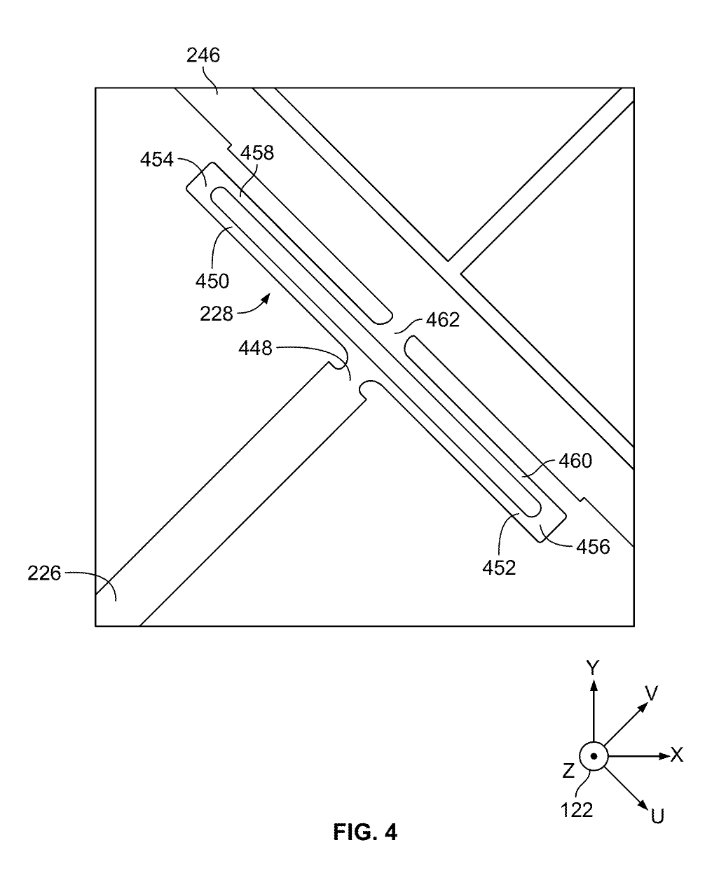

FIG. 4 depicts an enlarged view of the area of interest 248 (FIG. 3), showing the coupling spring 228 in detail. The coupling spring 228 comprises a coupling joint 448, flex arms 450, 452, 458, and 460, forks 454 and 456, and a coupling joint 462. The coupling spring 228 is connected to the distal end of the arm 226 at the coupling joint 448. The coupling joint 448 is connected to the flex arms 450 and 452. The flex arm 458 is connected to the flex arm 450 at the fork 454. The flex arm 460 is connected to the flex arm 452 at the fork 456. The flex arms 458 and 460 are connected to the proof mass 246 at the coupling joint 462. FIG. 4 depicts the coupling spring 228 when the arm 226 is at its neutral position. The coupling spring 228 is compliant along the major axis (aligned with the v axis when at rest) and stiff along the minor axis (aligned with the u axis when at rest).

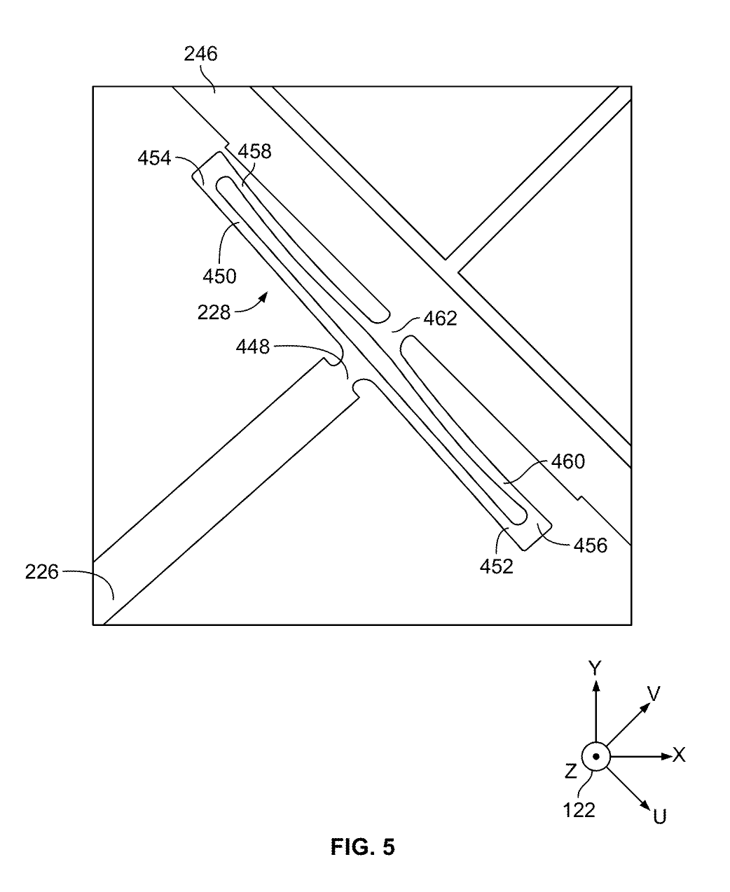

FIG. 5 depicts an enlarged area of interest 248 (FIG. 3) and in particular, the coupling spring 228 when the arm 226 is rotated clockwise from its neutral position. The coupling spring 228 has transmitted the u component of this rotation to the proof mass 246 while preventing the proof mass 246 from moving in the v direction. The coupling spring 228 allows the v component of distance between the distal end of the arm 226 and the proof mass 246 to increase by deforming in the v direction. This deformation of the coupling spring 228 causes the flex arms 450, 452, 458, and 460 to bend. This deformation of the coupling spring 228 also causes the fork 454 to move closer to the proof mass 246 while the fork 456 moves further away. The geometry of the coupling spring 228 is deflected to result in this bending. This bending behavior provides the combination of compliance in the v direction and rigidity in the u direction. Accordingly, the geometry of the coupling spring allows the proof mass 246 to move substantially only in the u direction when the arm 226 is rotated about the z axis.

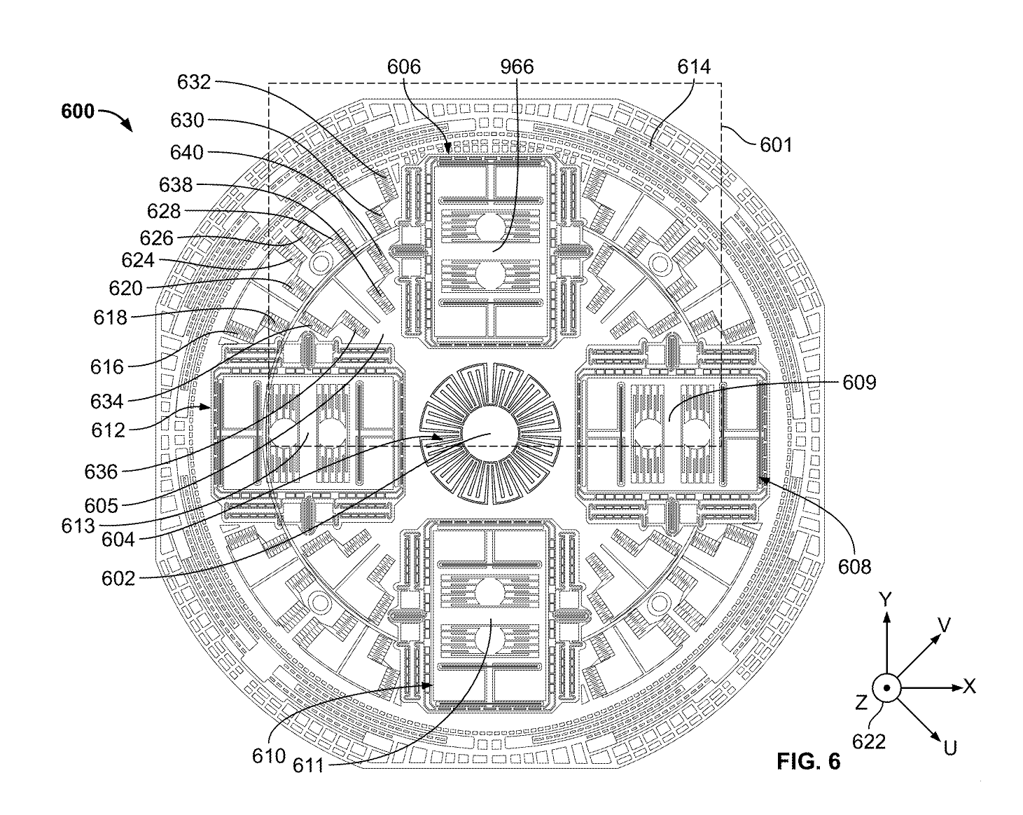

FIG. 6 depicts an inertial sensor 600 with springs that convert rotational motion to linear motion. FIG. 6 also depicts an area of interest 601. The inertial sensor 600 includes a central anchor 602 and a rotational spring 604. The inertial sensor 600 also includes a rotational drive comprising thirty-two drive combs, eight of which are labeled in FIG. 6 as drive combs 616, 618, 620, 624, 626, 628, 630, and 632. The inertial sensor 600 includes twelve drive sense combs, four of which are labeled in FIG. 6 as drive sense combs 634, 636, 638, and 640. The inertial sensor 600 includes a drive frame 605, which is connected to the central anchor 602 by the rotational spring 604. FIG. 6 also depicts a coordinate system 622 with an x-y-z coordinate system sharing a z-axis and an origin with a u-v-z coordinate system. While the coordinate system 622 is depicted offset from the inertial sensor 600 for clarity, the origin of the coordinate system 622 is located at the center of the central anchor 602. The x- and y-axes are orthogonal to each other. The u and v axes are orthogonal to each other and are rotated by −45 degrees from the x- and y-axes, respectively.

The drive combs (e.g., 616, 618, 620, 624, 626, 628, 630, and 632) cause the drive frame 605 to rotate about the z-axis. The drive sense combs (e.g., 634, 636, 638, and 640) provide output signals that can be used for closed-loop control of the drive combs (e.g., 616, 618, 620, 624, 626, 628, 630, and 632), measurement of the velocity of the drive frame 605, or both. In some examples, some of the drive sense combs (e.g., 634, 636, 638, and 640) are used for closed-loop control and some are used for measuring the velocity of the drive frame 605. The inertial sensor 600 also includes TDS structure 614. The TDS structure 614 produces a nonlinear capacitive signal used to measure drive velocity of the drive frame 605. The drive velocity of the drive frame 605 can be determined using the systems and methods described with reference to FIGS. 17-30.

The inertial sensor 600 includes gyro subassemblies 606, 608, 610, and 612. The gyro subassemblies 606 and 610 include proof masses 966 and 611, respectively, both configured to deflect in the y and z directions due to Coriolis forces when the inertial sensor 600 is rotated about the z- and y-axes, respectively. The gyroscope subassemblies 608 and 612 contain proof masses 609 and 613, respectively, both configured to deflect in the x and z directions due to Coriolis forces when the inertial sensor 600 is rotated about the z- and y-axes, respectively.

In some examples, the inertial sensor 600 does not contain a TDS structure 614 or other TDS structure and uses the drive sense combs (e.g., 634, 636, 638, and 640) for both velocity measurement and drive comb regulation. In some examples, the inertial sensor 600 does not include drive sense combs (e.g., 634, 636, 638, and 640) and uses the TDS structure, e.g., 614 for both velocity measurement and drive comb regulation. In some examples, the inertial sensor 600 contains both TDS structures 614 and/or others and drive sense combs (e.g., 634, 636, 638, and 640) and uses the TDS structure 614 and/or other TDS structures for drive comb regulation and the drive sense combs (e.g., 634, 636, 638, and 640) for velocity measurement. In some examples, the inertial sensor 600 uses the TDS structure 614 and/or others for velocity measurement and the drive sense combs (e.g., 634, 636, 638, and 640) for drive comb regulation.

In some examples, the inertial sensor 600 does not have a central anchor 602. In these examples, the drive frame 605 is anchored to the bottom layer and/or the cap layer at an outer location.

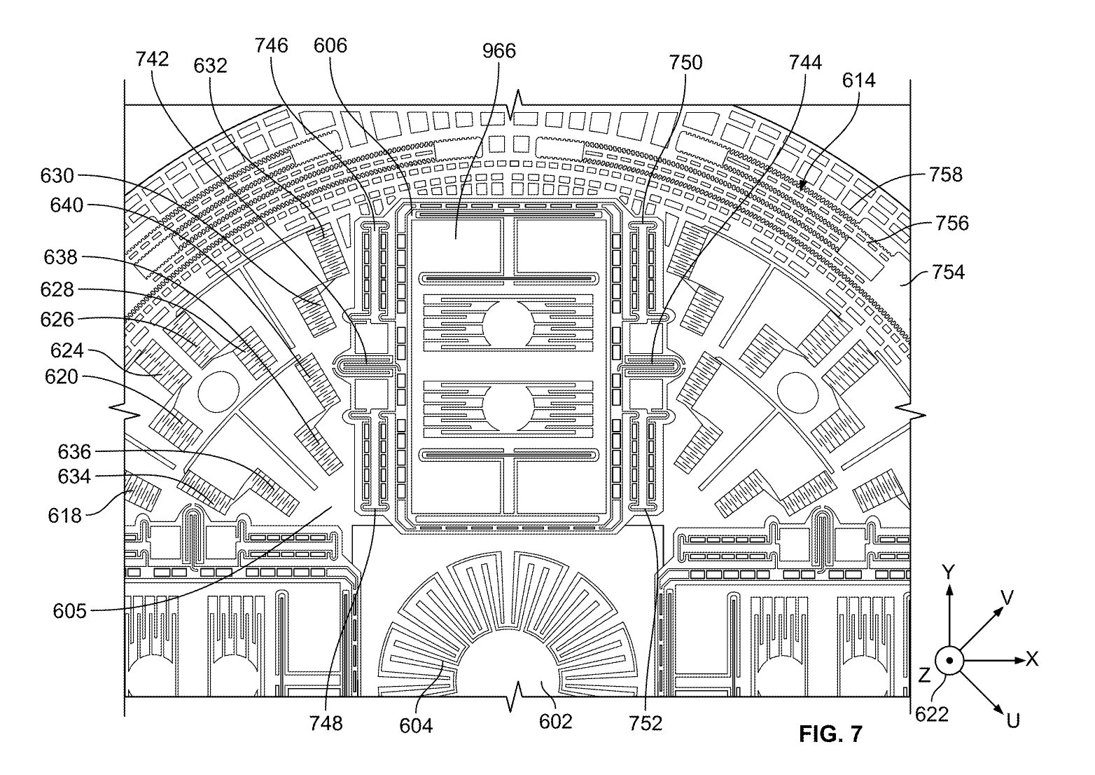

FIG. 7 depicts an enlarged view of the area of interest 601 (FIG. 6). At the center of FIG. 7 is the gyroscope subassembly 606. The gyroscope subassembly 606 is connected to the drive frame 605 by coupling springs 742 and 744 and by drive springs 746, 748, 750, and 752. The drive springs and coupling springs depicted in FIG. 7 operate in a similar manner as the drive springs (e.g., 225 and 227) and coupling springs (e.g., 228) depicted in FIGS. 1-5, but have different geometry. In contrast to the coupling spring 228 (FIG. 2), which is located radially inward from the proof mass 246 (FIG. 2), the coupling springs 742 and 744 of the inertial sensor 600 are located circumferentially adjacent to the gyroscope subassembly 606. The coupling springs 742 and 744 are rigid in the x direction but are compliant in the y direction. Thus, the coupling springs 742 and 744 transfer motion in the x direction from the drive frame 605 to the gyroscope subassembly 606 while allowing relative motion between the drive frame 605 and the gyroscope subassembly 606 in the y direction. The drive springs 746, 748, 750, and 752 are rigid in the y direction but are compliant in the x direction. Because the drive springs 746, 748, 750, and 752 are not perfect springs, they are not perfectly rigid and thus have finite stiffnesses. Thus, the drive springs 746, 748, 750, and 752 do allow some motion of the gyroscope subassembly 606 in the y direction. However, the drive springs 746, 748, 750, and 752 have high stiffnesses in the y direction such that motion of the gyroscope subassembly 606 in the y direction is small. Thus, the drive springs 746, 748, 750, and 752 allow the gyroscope subassembly 606 to move in the x direction but substantially prevent it from moving in the y direction. Accordingly, the combination of the coupling springs 740 and 744 and the drive springs 746, 748, 750, and 752, with appropriately tailored geometry, stiffness and compliance, convert rotational motion of the drive frame 605 about the z-axis into linear motion of the gyroscope subassembly 606 substantially along the x-axis.

FIG. 7 also depicts details of the TDS structure 614. The TDS structure 614 includes movable teeth 758, fixed teeth 756, and an anchor 754. The anchor 754 is anchored to the bottom layer and/or the cap layer and does not move relative to the central anchor 602. Thus, the fixed teeth 756 also do not move relative to the central anchor 602. The movable teeth 758 are connected to the drive frame 605 and rotate with it. As the movable teeth 758 rotate about the z-axis, the capacitance between the fixed teeth 756 and the movable teeth 758 varies nonlinearly. The velocity of the drive frame 605 can be determined using the systems and methods described with reference to FIGS. 17-30. The velocity of the drive frame 605 is then used for determining rates of rotation acting upon the inertial sensor 600.

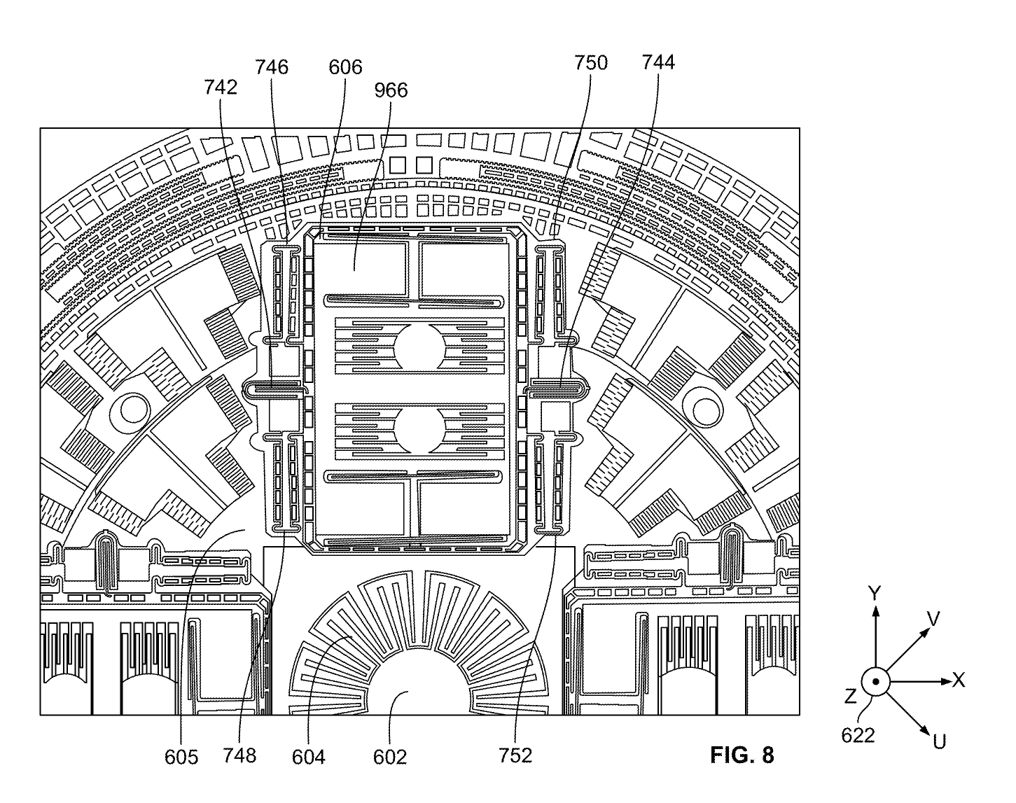

FIG. 8 depicts an enlarged view of area of interest 601 (FIG. 6) when the drive combs have caused the drive frame 605 to rotate counterclockwise about the z-axis. The coupling springs 742 and 744 have transmitted motion in the x direction to the gyroscope subassembly 606 while allowing relative motion in the y direction between the gyroscope subassembly 606 and the drive frame 605. The drive springs 746, 748, 750, and 752 have prevented any relative motion in the y direction between the gyroscope subassembly 606 and the drive frame 605 while allowing relative motion in the x direction. The drive springs 746 and 748 have closed slightly while the drive springs 750 and 752 have opened slightly. The point at which the coupling springs 742 attaches to the drive frame 605 is offset in the −y direction from the point at which the coupling spring 742 attaches to the gyroscope subassembly 606. Likewise, the point at which the coupling spring 744 attaches to the drive frame 605 is offset in the +y direction from the point at which the coupling spring 744 attaches to the gyroscope subassembly 606. Because the coupling springs 742 and 744 allow this offset, they allow relative motion in the y direction. Because the coupling springs 742 and 744 and drive springs 746, 748, 750, and 752 are symmetric, they behave symmetrically when the drive frame 605 rotates clockwise.

The gyroscope subassembly 606 contains a proof mass 966 that is deflected by a Coriolis force in response to rotations of the inertial sensor 600. When the inertial sensor 600 is rotated about the y-axis, a Coriolis force causes the proof mass 966 to deflect in the z direction. When the inertial sensor 600 is rotated about the z-axis, a Coriolis force causes the proof mass 966 to deflect in the y direction.

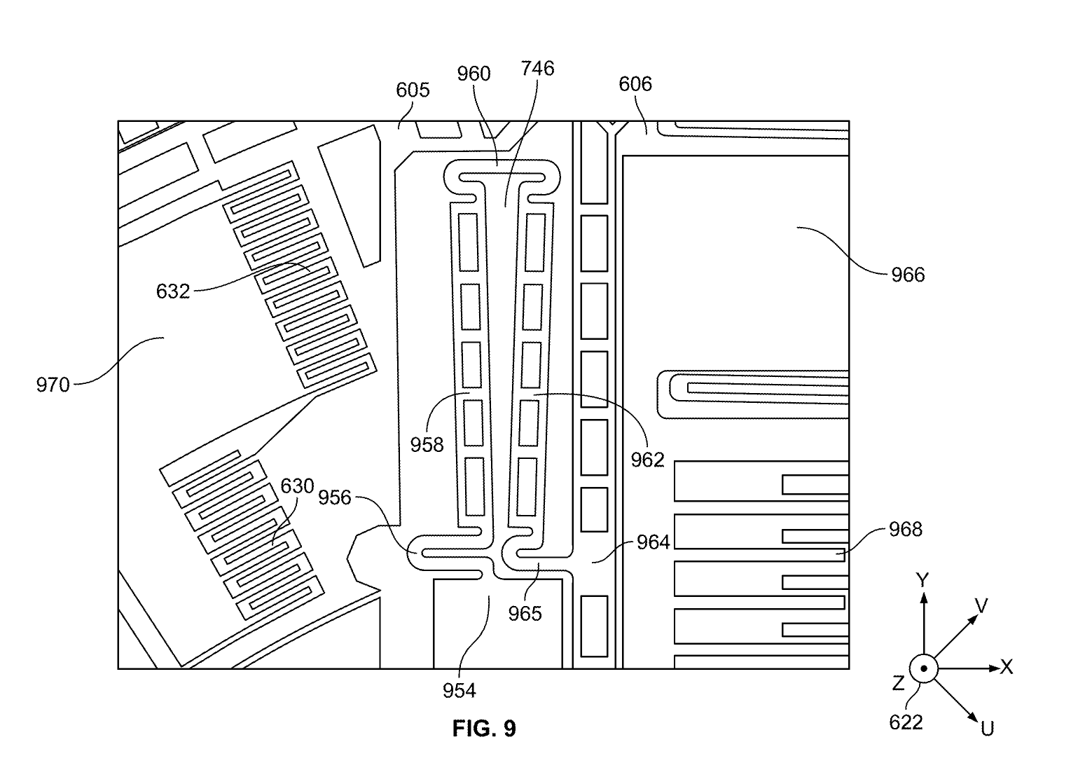

FIG. 9 depicts an enlarged view of part of the gyroscope subassembly 606, and in particular the drive spring 746 when the drive combs (e.g., 616, 618, 620, 624, 626, 628, 630, and 632) have rotated the drive frame 605 counterclockwise about the z-axis. FIG. 9 depicts anchors 954 and 970 which are anchored to the bottom layer and/or the cap layer and do not move relative to the central anchor 602 (FIG. 6). The drive spring 746 includes an anchor fork 956, an anchor arm 958, a middle fork 960, a drive arm 962, and a drive fork 965. The anchor 954 is connected to the proximal end of the anchor arm 958 by the anchor fork 956. The distal end of the anchor arm 958 is connected to the distal end of the drive arm 962 by the middle fork 960. The proximal end of the drive arm 962 is connected to a drive frame 964 of the gyroscope subassembly 606 by the drive fork 965. The forks 956, 960, and 964 flex to allow the drive frame 964 to move in the −x direction, but the arms 958 and 962 are rigid, substantially preventing the drive frame 964 from moving in the y direction.

FIG. 9 also depicts a proof mass 966 and a sense comb 968. The sense comb 968 is configured for detecting motion of the proof mass 966 in they direction.

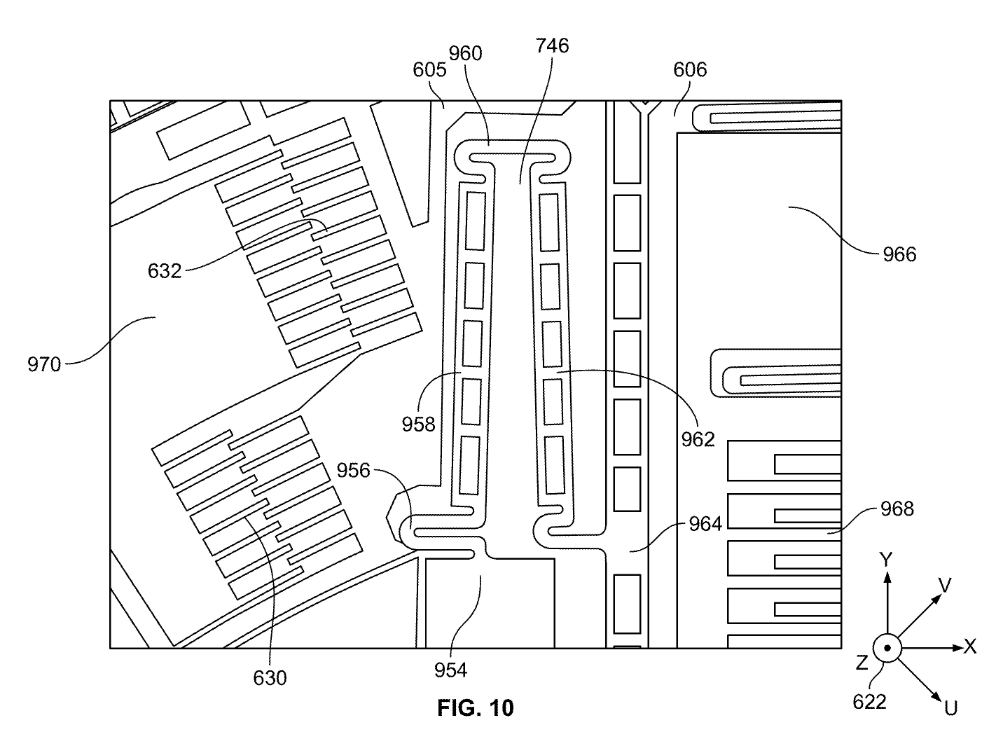

FIG. 10 depicts an enlarged view of part of the gyroscope subassembly 606, and in particular the drive spring 746, when the drive combs (e.g., 616, 618, 620, 624, 626, 628, 630, and 632) have rotated the drive frame 605 clockwise about the z-axis from its neutral position. The forks 956, 960, and 964 have flexed, allowing the drive spring 746 to expand slightly. This opening of the drive spring 746 allows the drive frame 964 to move in the x direction. Because the arms 958 and 962 are rigid, the drive spring 746 prevents the drive frame 964 from moving in the y direction. Accordingly, the drive spring 746 allows the gyroscope subassembly 606 to move in the x direction but substantially prevents it from moving in the y direction.

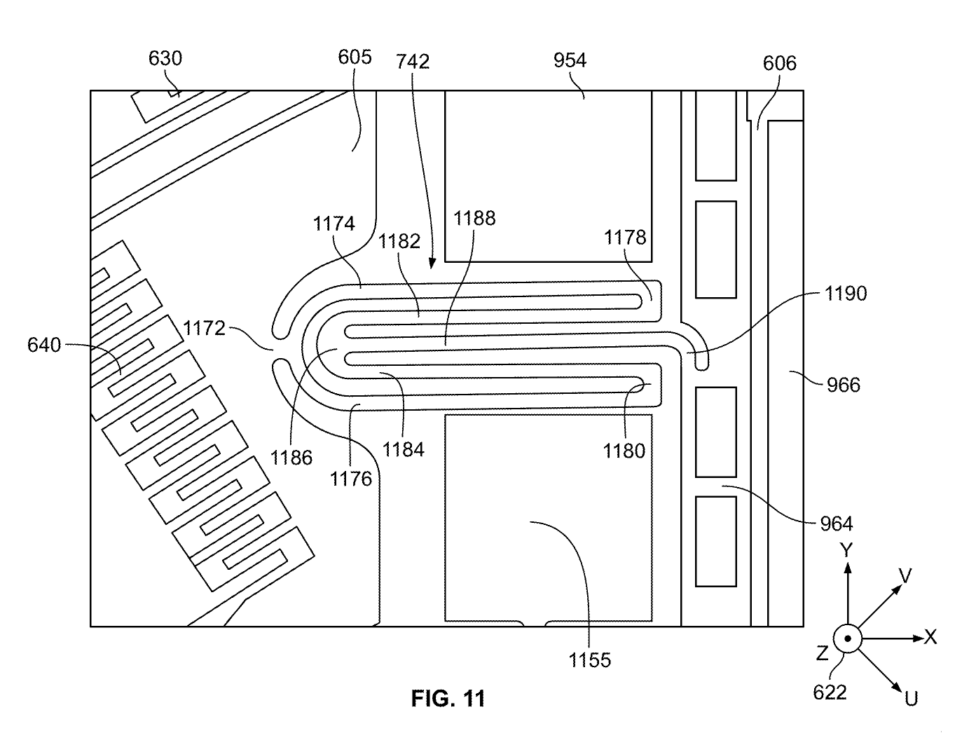

FIG. 11 depicts an enlarged view of part of the gyroscope subassembly 606, and in particular the coupling spring 742, when the drive combs have rotated the drive frame 964 counterclockwise about the z-axis. The coupling spring 742 includes a driving fork 1172, driving arms 1174 and 1176, middle forks 1178 and 1180, middle arms 1182 and 1184, driven fork 1186, driven arm 1188, and driven fork 1190. The proximal ends of the driving arms 1174 and 1176 are connected to the drive frame 605 by the driving fork 1172. The distal end of the middle arm 1182 is connected to the distal end of the driving arm 1174 by the middle fork 1178. The distal end of the driving arm 1176 is connected to the distal end of the middle arm 1184 by the middle fork 1180. The proximal ends of the middle arms 1182 and 1184 are connected to each other and to the proximal end of the driven arm 1188 by the driven fork 1186. The distal end of the driven arm 1188 is connected to the drive frame 964 by the driven fork 1190. As the drive frame 605 rotates about the z-axis, the forks 1172, 1178, 1180, 1186, and 1190 flex, allowing the drive frame 605 to move in the y direction relative to the drive frame 964. The arms 1174, 1176, 1182, 1184, and 1188 are rigid in the x direction, thus transmitting the x component of the rotation of the drive frame 605 to the drive frame 964. Because relative motion between the drive frames is allowed in the y direction, the coupling spring 742 is compliant in the y direction. Because the coupling spring 742, which connects the gyroscope subassembly 606 to the drive frame 605, is compliant in the y direction but rigid in the x direction, the coupling spring 742 transmits only the x component of the rotation of the drive frame 605 to the gyroscope subassembly 606. The coupling springs 742 and 744 (FIGS. 7-8) have symmetric geometry.

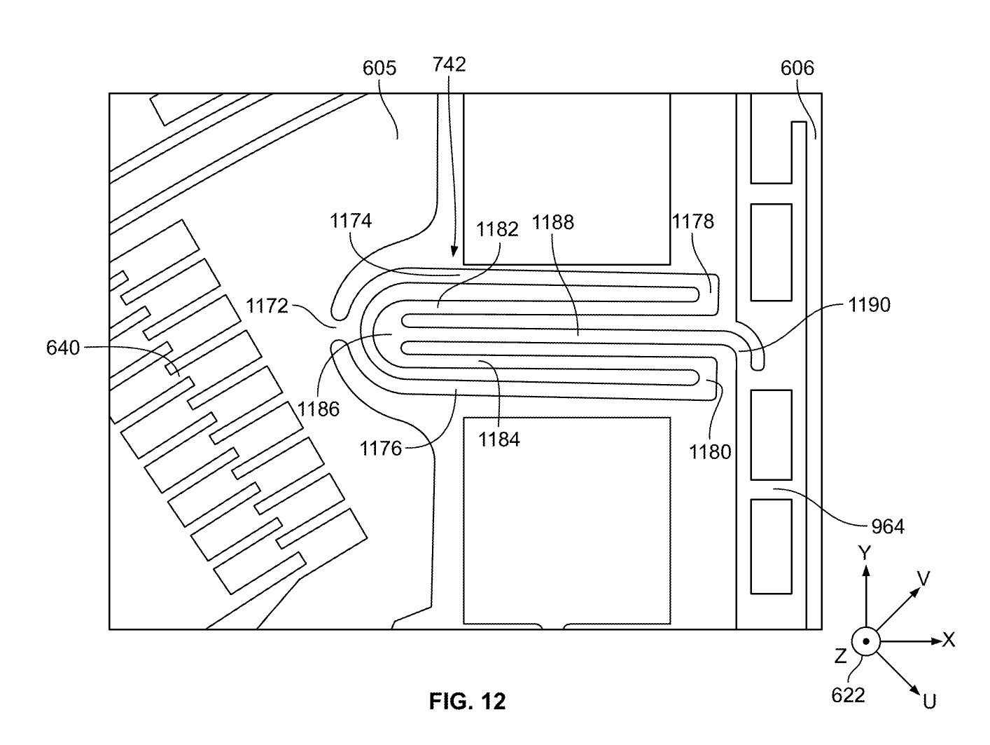

FIG. 12 depicts an enlarged view of part of the gyroscope subassembly 606, and in particular the coupling spring 742, when the drive combs (e.g., 616, 618, 620, 624, 626, 628, 630, and 632) have rotated the drive frame 605 clockwise about the z-axis from its neutral position. The forks 1172, 1178, 1180, 1186, and 1190 have flexed, allowing the driving fork 1172 to move in the +y direction relative to the driven fork 1190. The driven fork 1190 does not move in the y direction, while the position of the driving fork 1172 moves in an arc centered on the z-axis as the drive frame 605 rotates. The coupling spring 742 transmits only the x component of the motion along this arc to the drive frame 964 and the gyroscope subassembly 606. Accordingly, the coupling spring 742, in conjunction with the coupling spring 744 and the drive springs 746, 748, 750, and 752, converts rotational motion of the drive frame 605 about the z-axis into linear motion of the gyroscope subassembly 606 along the x-axis.

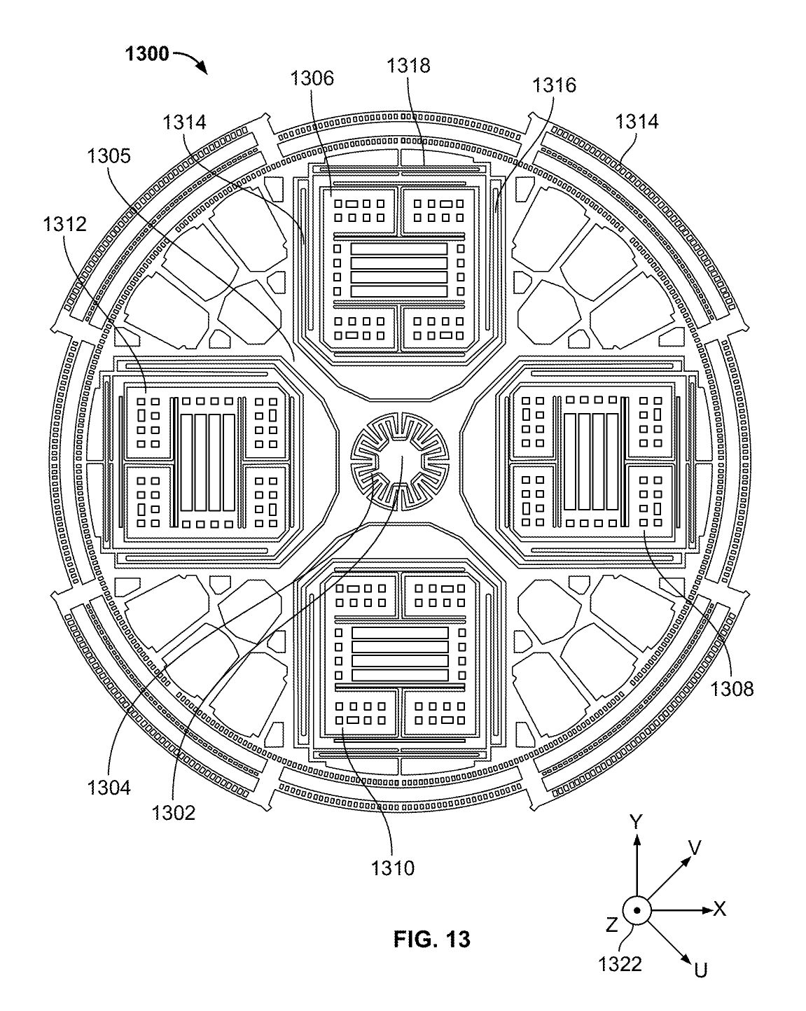

FIG. 13 depicts an inertial sensor 1300 with springs that convert rotational motion to linear motion. The inertial sensor 1300 includes a central anchor 1302, which is anchored to the bottom layer (not shown) and/or the cap layer (not shown) below a device layer of the inertial sensor 1300 depicted in FIG. 13. The inertial sensor 1300 includes a drive frame 1305 connected to the central anchor 1302 by a rotational spring 1304. The inertial sensor 1300 includes a rotational drive comprising a plurality of drive combs (not shown) which cause the drive frame 1305 to rotationally oscillate about the z-axis. FIG. 13 also depicts a coordinate system 1322 with an x-y-z coordinate system sharing a z-axis and an origin with a u-v-z coordinate system. While the coordinate system 1322 is depicted offset from the inertial sensor 1300 for clarity, the origin of the coordinate system 1322 is located at the center of the central anchor 1302. The x- and y-axes are orthogonal to each other. The u- and v-axes are orthogonal to each other and are rotated by −45 degrees from the x- and y-axes, respectively. The inertial sensor 1300 includes TDS structures 1314 (only part of which are shown) and drive sense combs (not shown) to measure the velocity of the drive frame 1305 and to regulate the drive combs in closed-loop control. The velocity and amplitude of motion of the drive frame 1305 can be determined using the systems and methods described with reference to FIGS. 17-30.

In some examples, the inertial sensor 1300 does not contain a TDS structure and uses the drive sense combs for both velocity measurement and drive comb regulation. In some examples, the inertial sensor 1300 does not include drive sense combs and uses the TDS structure for both velocity measurement and drive comb regulation. In some examples, the inertial sensor 1300 contains both TDS structures and drive sense combs and uses the TDS structure for drive comb regulation and the drive sense combs for velocity measurement. In some examples, the inertial sensor 1300 uses the TDS structure for velocity measurement and the drive sense combs for drive comb regulation.

In some examples, the inertial sensor 1300 does not have a central anchor 1302. In these examples, the drive frame is anchored to the bottom layer and/or the cap layer at an outer location.

The inertial sensor 1300 includes gyroscope subassemblies 1306, 1308, 1310, and 1312. When the inertial sensor 1300 is rotated about the x-axis, a Coriolis force causes proof masses of the gyroscope subassemblies 1308 and 1312 to deflect in the z direction. When the inertial sensor 1300 is rotated about the z-axis, a Coriolis force causes the proof masses of the gyroscope subassemblies 1306 and 1310 to deflect in they direction and the proof masses of the gyroscope subassemblies 1308 and 1312 to deflect the x direction. When the inertial sensor 1300 is rotated about the y-axis, a Coriolis force causes proof masses of the gyroscope subassemblies 1306 and 1310 to deflect in the z direction. Electrodes (not shown) mounted either above or below the device layer depicted in FIG. 13 detect the deflection in the z direction in the proof masses of the gyroscope subassemblies 1306, 1308, 1310, and 1312. These electrodes measure the respective deflections by measuring a change in capacitance. Electrodes (not shown) anchored to the bottom layer and/or the cap layer but extending into the device layer measure the deflection of the proof masses of the gyroscope subassemblies 1306, 1308, 1310, and 1312 in the x-y plane by measuring a change in capacitance. The inertial sensor 1300 also includes TDS structures (not shown) configured to measure motion of the proof masses of the gyroscope subassemblies 1308 and 1312 along the y-axis. The motion measured by the TDS structures can be used to calculate velocity of the drive frame 1305, acceleration of the inertial sensor 1300 in the y direction, or both.

The inertial sensor 1300 includes four coupling springs, one of which is a coupling spring 1318. In contrast to the coupling spring 228 of the inertial sensor 100 and the coupling springs 742 and 744 of the inertial sensor 600, the coupling spring 1318 is located radially outward from the gyroscope subassembly 1306. The inertial sensor 1300 also includes eight drive springs, two of which are drive springs 1314 and 1316.

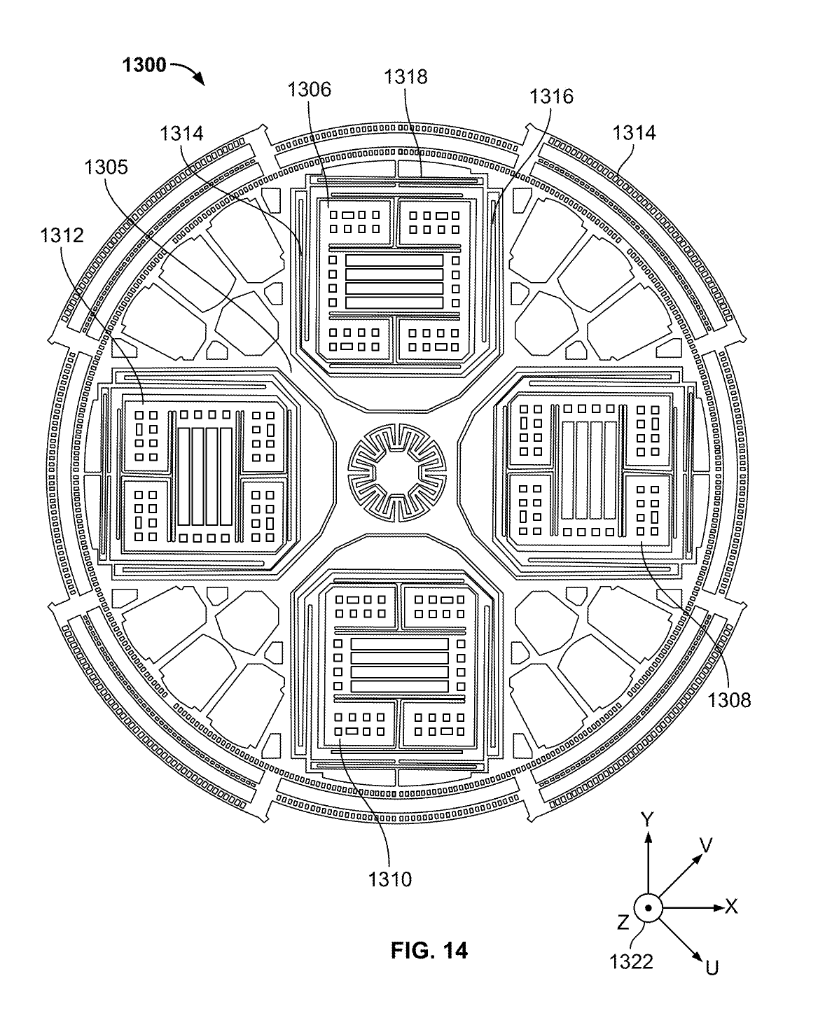

FIG. 14 depicts the inertial sensor 1300 when the drive combs have rotated the drive frame 1305 counterclockwise about the z-axis from its neutral position. The drive springs and couplings springs have converted this rotational motion of the drive frame 1305 into linear motion in the −x direction for the gyroscope subassembly 1306, linear motion in the +x direction for the gyroscope subassembly 1310, linear motion in the +y direction for the gyroscope subassembly 1308, and linear motion in the −y direction for the gyroscope subassembly 1312.

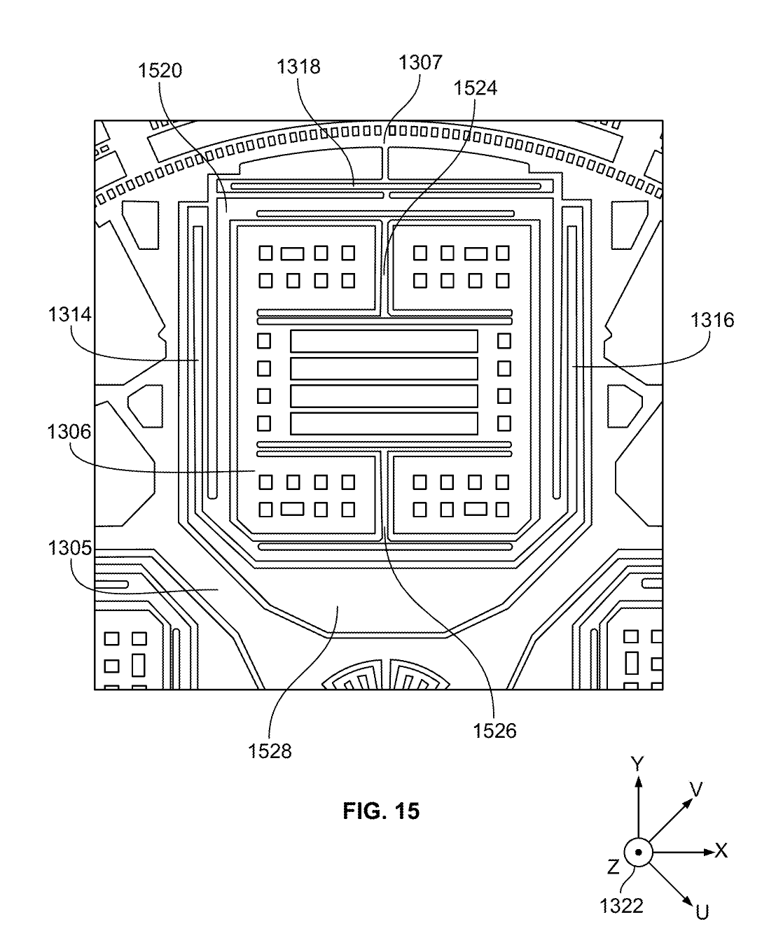

FIG. 15 depicts an enlarged view of the gyroscope subassembly 1306 when the drive frame 1305 is in its neutral position. FIG. 15 depicts an anchor 1528 that is anchored to the bottom layer (not shown) and/or the cap layer (not shown) and does not move relative to the central anchor 1302. The anchor 1528 is connected to the drive springs 1314 and 1316. The drive springs 1314 and 1316 have a similar geometry to, and function in a similar manner as, the drive springs 225 (FIG. 2), 227 (FIG. 2), 746 (FIG. 7), 748 (FIG. 7), 750 (FIG. 7), and 752 (FIG. 7). The coupling spring 1318 is connected to an outer rim 1307 of the drive frame 1305. The outer rim 1307 is rigidly connected to the drive frame 1305 and rotates with it. The coupling spring 1318 has a similar geometry and functions in a similar manner as the coupling spring 228 (FIG. 2). FIG. 15 also depicts the springs 1524 and 1526 which allow a proof mass of the gyroscope subassembly 1306 to deflect in the z direction.

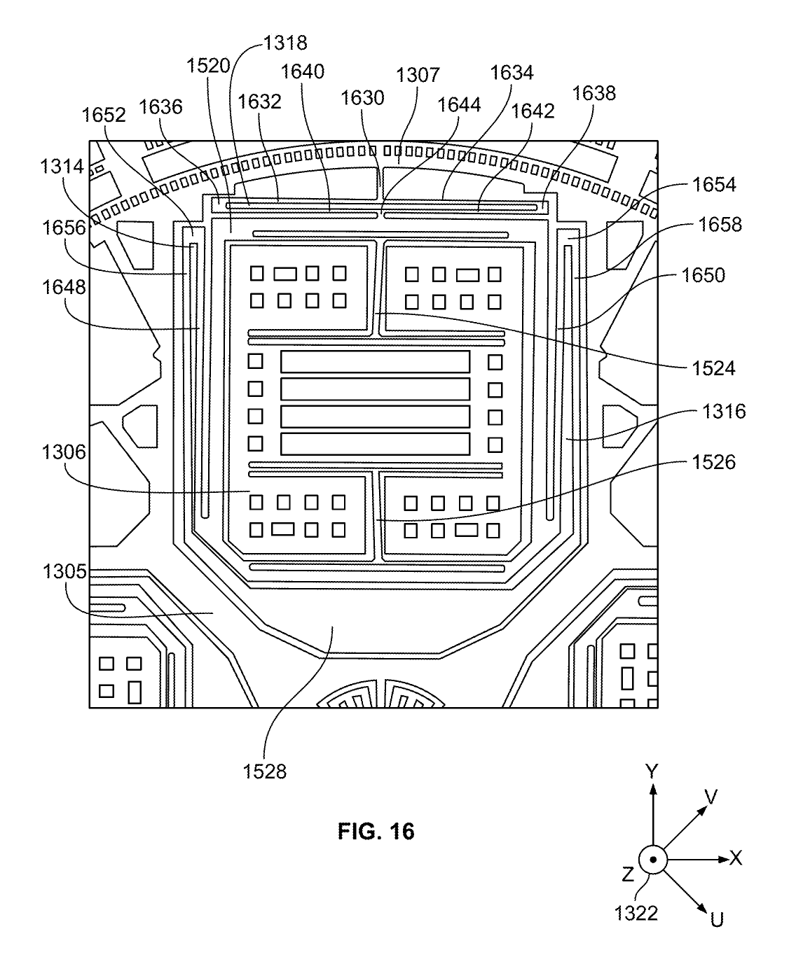

FIG. 16 depicts an enlarged view of the gyroscope subassembly 1306 when the drive combs have rotated the drive frame 1305 counterclockwise from its neutral position. FIG. 15 also depicts a drive frame 1520 of the gyroscope subassembly 1306. The drive frame 1520 receives the motion in the x direction transmitted by the coupling spring 1318 and transmits that x motion to a proof mass of the gyroscope subassembly 1306. The coupling spring 1318 includes coupling links 1630 and 1644, flex arms 1632, 1634, 1640, and 1642, and forks 1636 and 1638. The distal end of the coupling link 1630 is connected to the outer rim 1307 of the drive frame 1305. The proximal end of the coupling link 1630 is connected to the flex arms 1632 and 1634. The left ends of the flex arms 1632 and 1640 are connected by the fork 1636, and the right ends of the flex arms 1634 and 1642 are connected by the fork 1638. The right end of the flex arm 1640 and the left end of the flex arm 1642 are connected to the drive frame 1520 by the coupling link 1644. Because the drive frame 1305 is rotated from its neutral position, the flex arms 1632, 1634, 1640, and 1642 bend slightly to allow relative motion in the y direction between the coupling links 1630 and 1644 while transmitting the x component of the rotation to the drive frame 1520 by the coupling link 1644.

The drive spring 1314 includes an anchor arm 1656, a fork 1652, and a drive arm 1648. The drive spring 1316 includes an anchor arm 1658, a fork 1654, and a drive arm 1650. The respective proximal ends of the anchor arms 1656 and 1658 are connected to the anchor 1528. The distal end of the anchor arm 1656 is connected to the distal end of the drive arm 1648 by the fork 1652. Likewise, the distal end of the anchor arm 1658 is connected to the distal end of the drive arm 1650 by the fork 1654. The proximal ends of the drive arms 1648 and 1650 are connected to the drive frame 1520 by respective forks.

The drive springs 1314 and 1316 are stiff in they direction but compliant in the x direction. Thus, as the coupling spring 1318 transmits the x component of rotation to the drive frame 1520, the drive springs 1314 and 1316 prevent the drive frame 1520 from moving in the y direction. As the drive frame 1305 rotates counterclockwise, the fork 1652 flexes to allow the drive spring 1314 to close slightly and the fork 1654 flexes to allow the drive spring 1316 to open slightly. This flexing, opening, and closing allows the drive frame 1520 to move in the x direction. Because the drive springs 1314 and 1316 are not perfect springs, they are not perfectly rigid and thus have finite stiffnesses. Thus, the drive springs 1314 and 1316 do allow some motion of the drive frame 1520 in the y direction. However, the drive springs 1314 and 1316 have high stiffnesses in the y direction such that motion of the drive frame 1520 in the y direction is small. Because of the geometry, stiffness, and compliance of the coupling spring 1318 and the drive springs 1314 and 1316, the inertial sensor 1300 converts the rotational motion of the drive frame 1305 into linear motion of the gyroscope subassembly 1306 substantially along the x-axis.

FIG. 17 depicts three views 1700, 1730, and 1760, each showing a schematic representation of parts of a moveable element 1702 and a fixed element 1704. The TDS structures described herein can include the moveable element 1702 and the fixed element 1704. The oscillating mass of the TDS structure can include the moveable element 1702. The movable element 1702 and the fixed element 1704 depicted in FIG. 17 each include a plurality of structures, or beams. In particular, the fixed element 1704 includes beams 1706a, 1706b, and 1706c (collectively, beams 1706). The moveable element 1702 depicted in FIG. 17 includes beams 1708a and 1708b (collectively, beams 1708). The moveable element 1702 is separated from the fixed element 1704 by a distance WO 1732. The distance WO 1732 can change as the moveable element 1702 oscillates with respect to the fixed element 1704. The distance WO 1732 affects parasitic capacitance between the movable element 1702 and the fixed element 1704. The distance WO 1732 is selected to minimize parasitic capacitance when the movable element 1702 is in the rest position, while maintaining manufacturability of the sensor. The view 1760 depicts an area of interest noted by the rectangle 1740 of view 1730. FIG. 17 depicts an example of TDS structures with teeth on parallel beams. In other examples, TDS structures include teeth on other geometrics. However, the same general principles described with reference to FIGS. 17-30 apply to TDS structures with other geometrics.

Each of the beams 1706 and 1708 includes multiple sub-structures, or teeth, protruding perpendicularly to the long axis of the beams. The beam 1706b includes teeth 1710a, 1710b, and 1710c (collectively, teeth 1710). The beam 1708b includes teeth 1712a, 1712b and 1712c (collectively, teeth 1712). Adjacent teeth on a beam are equally spaced according to a pitch 1762. Each of the teeth 1710 and 1712 has a width defined by the line width 1766 and a depth defined by a corrugation depth 1768. Opposing teeth are separated by a tooth gap 1764. As the moveable beam 1708b oscillates along the moving axis 1701 with respect to the fixed beam 1706b, the tooth gap 1764 remains unchanged. In some examples, manufacturing imperfections cause the tooth spacing to deviate from the pitch 1762. However, provided that the deviation is negligible compared to the pitch 1762, the deviation does not significantly impact operation of the sensor and can be neglected for the purposes of this disclosure.

A capacitance exists between the fixed beam 1706b and the moveable beam 1708b. As the moveable beam 1708b oscillates along the moving axis 1701 with respect to the fixed beam 1706b, the capacitance changes. The capacitance increases as opposing teeth of the teeth 1710 and 1712 align with each other and decreases as opposing teeth become less aligned with each other. At the position depicted in the view 1760, the capacitance is at a maximum and the teeth 1710 are in an aligned position with respect to the teeth 1712. As the moveable beam moves monotonically along the moving axis 1701, the capacitance changes non-monotonically, since a maximum in capacitance occurs as the teeth 1710 and 1712 are in an aligned position.

The capacitance can be degenerate, meaning that the same value of capacitance can occur at different displacements of the moveable beam 1708b. When the moveable beam 1708b has moved from its rest position by a distance equal to the pitch 1762, the capacitance is the same as when the moveable beam 1708b is in the rest position.

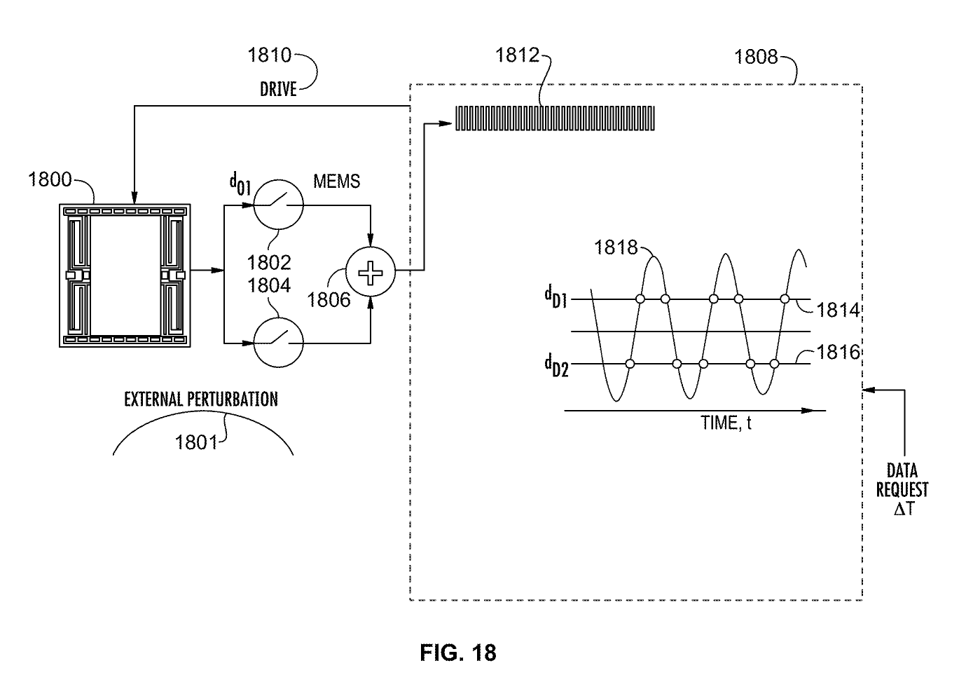

FIG. 18 schematically depicts an exemplary process used to extract inertial information from an inertial sensor with periodic geometry. FIG. 18 includes an inertial sensor 1800 which experiences an external perturbation 1801. The inertial sensor 1800 can include the system 100, and the external perturbation 1801 can include the input inertial parameter 102. A drive signal 1810 causes a movable portion of the sensor 1800 to oscillate. The moveable portion can be the moveable element 1702. An analog frontend (AFE) electrically connected to the moveable element 1702 and to the fixed element 1704 measures the capacitance between them and outputs a signal based on the capacitance. The AFE can do this by measuring a capacitive current or a charge. Zero-crossings of the AFE output signal occur when the AFE output signal momentarily has a magnitude of zero. Zero-crossings of an output signal from the inertial sensor 1800 are generated at 1802 and 1804 and combined at 1806 into a combined signal. A signal processing module 1808 processes the combined analog signal to determine inertial information. One or more processes can convert the combined analog signal into a rectangular waveform 1812. This can be accomplished using a comparator, by amplifying the analog signal to the rails, or by other methods.

The rectangular waveform 1812 comprises a rectangular pulse stream having high and low values, with no substantial time spent transitioning between high and low values. Transitions between high and low values correspond to zero-crossings of the combined analog signal. The transitions between high and low values and zero-crossings occur when a displacement 1818 of the movable element 1702 crosses reference levels 1814 and 1816. The reference levels 1814 and 1816 correspond to physical locations of movable portions of the sensor 1800. Because the zero-crossings are associated with specific physical locations, displacement information can be reliably determined independent of drift, creep and other factors which tend to degrade performance of inertial sensors.

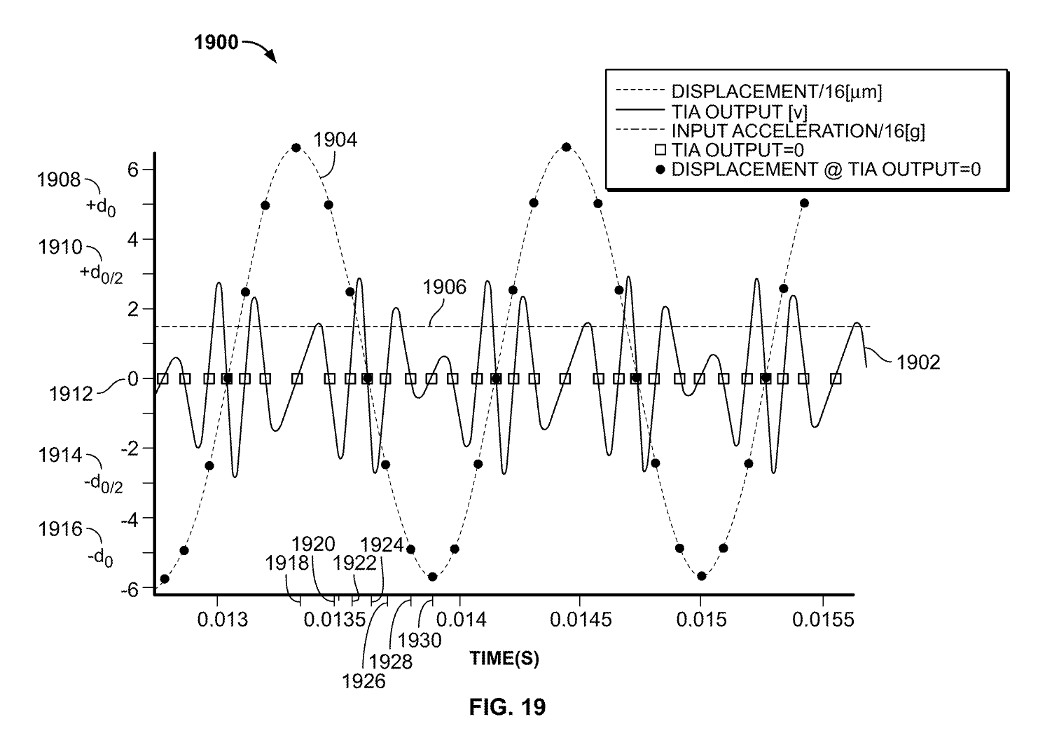

FIG. 19 depicts a graph 1900 which represents the association of analog signals derived from the inertial sensor 1800 with zero-crossing times and displacements of the inertial sensor. The graph 1900 represents signals derived from an oscillator in which opposing teeth are aligned at the rest position. The graph 1900 includes curves 1902, 1904 and 1906. The curve 1902 represents an output of an AFE such as a transimpedance amplifier (TIA). Since a TIA outputs a signal proportional to its input current, the curve 1902 represents a capacitive current measured between movable and fixed elements of an inertial device such as the inertial device 1800. The curve 1906 represents an input acceleration that is applied to the inertial device 1800. The input acceleration represented by the curve 1906 is a 15 g acceleration at 20 Hz. The curve 1904 represents displacement of the movable element of the inertial device 1800 as it oscillates.

FIG. 19 includes square symbols indicating points on the curve 1902 at which the curve 1902 crosses the zero level. These zero-crossings in the current represent local maxima or minima (extrema) of capacitance between the movable element and the fixed element of the inertial device, because capacitive current is proportional to the first derivative of capacitance. FIG. 19 includes circular symbols indicating points on the curve 1904 corresponding to times at which the curve 1902 crosses zero. The circular symbols indicate the correlation between physical position of a movable element of the oscillator and zero-crossing times of the outputs of signal 1902.

At the time 1918, the curve 1902 crosses zero because the displacement of the movable element of the oscillator is at a maximum and the oscillator is at rest, as indicated by the displacement curve 1904. Here, capacitance reaches a local extremum because the movable element has a velocity of zero, not necessarily because teeth or beams of the oscillator are aligned with opposing teeth or beams. At time 1920, the TIA output curve 1902 crosses zero because the oscillator displacement reaches the +d₀ location 1908. The +d₀ location 1908 corresponds to a displacement in a positive direction equal to the pitch distance and is a point at which opposing teeth or beams are aligned to produce maximum capacitance. At time 1922, the TIA output curve 1902 crosses zero because the movable element of the oscillator is at a position at which the teeth are anti-aligned. This occurs when the teeth of the movable element 1702 (FIG. 17) are in an aligned position with the centers of gaps between teeth of the fixed element 1704, resulting in a minimum in capacitance. This minimum in capacitance occurs at a location of +d₀/2 1910, corresponding to a displacement to one-half the pitch distance in the positive direction.

At time 1924, the TIA output curve 1902 crosses zero because teeth of the movable element 1702 (FIG. 17) are aligned with teeth of the fixed element 1704 (FIG. 17), producing a maximum in capacitance. The time 1924 corresponds to a time at which the movable element is at the rest position, indicated by the zero displacement 1912 on the curve 1904. At time 1926, the TIA output 2002 crosses zero because teeth of the movable element 1702 (FIG. 17) are anti-aligned with teeth of the fixed element 1704 (FIG. 17), producing a local minimum in capacitance. This anti-alignment occurs at a displacement of −d₀/2 1914, corresponding to a displacement of one-half the pitch distance in the negative direction.

At time 1928, the TIA output 1902 crosses zero because the teeth of the movable element 1702 (FIG. 17) are in an aligned position with respect to the teeth of the fixed element 1704 (FIG. 17), creating a local maximum in capacitance. This local maximum in capacitance occurs at a displacement of −d₀ 1916, corresponding to a displacement equal to such distance in the negative direction. At time 1930, the TIA output curve 1902 crosses zero because the movable element 1702 (FIG. 17) has a velocity of zero as it reverses direction. This reversal of direction is illustrated by the displacement curve 1904. As at time 1918, when the movable element has a velocity of zero, capacitance is not changing with time and thus the current and TIA output (which are proportional to the first derivative of capacitance) are zero.

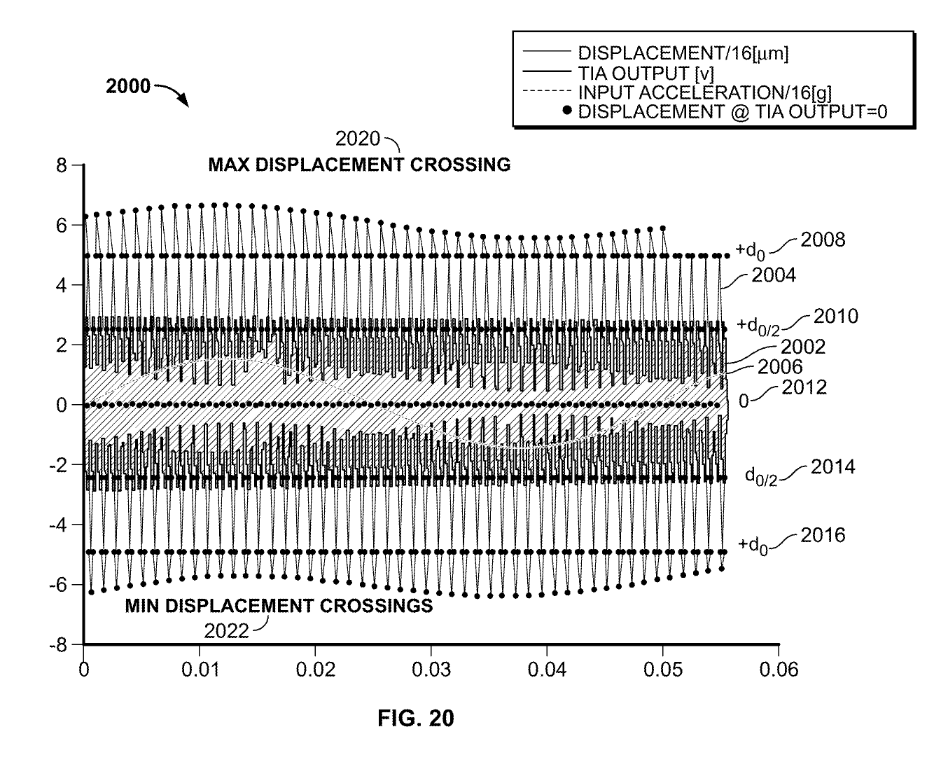

FIG. 20 depicts a graph 2000 showing the effect of an external perturbation on input and output signals of any of the inertial sensors described herein. The graph 2000 includes the TIA output curve 2002 which is similar to the TIA output curve 1902, the displacement curve 2004 which is similar to the displacement curve 1904, and the input acceleration curve 2006 which is similar to the input acceleration curve 1906. FIG. 20 also depicts the location+d₀ 2008 which is similar to the location+d₀ 1908, the location+d₀/2 2010 which is similar to the location +d₀/2 1910, the location 0 2012 which is similar to the location − 1912, the location −d₀/2 2014 which is similar to the location −d₀/2 1914, and the location −d₀ 2016 which is similar to the location −d₀ 1916. The graph 2000 depicts the same signals depicted in the graph 1900, and the only difference is that the graph 2000 represents a longer duration of time than the graph 1900. With a longer duration of time displayed in the graph 2000, the periodicity of the input acceleration curve 2006 is more easily discerned. In addition, maximum displacement crossings 2020 and minimum displacement crossings 2022 can be discerned in the graph 2000 to experience a similar periodicity. In contrast to the maximum displacement crossings 2020 and the minimum displacement crossings 2022, the amplitude of which varies with time, zero-crossings of the TIA output signal 1902 triggered by alignment or anti-alignment of teeth of the fixed and movable elements 1704 (FIG. 17) and 1702 (FIG. 17) at the locations +d₀ 2008, +d₀/2 2010, 0 2012, −d₀/2 2014, and −d₀ 2016 are stable with time. These reference crossings, the amplitude of which are stable with time, provide stable, drift-independent indications of oscillator displacement and can be used to extract inertial parameters.

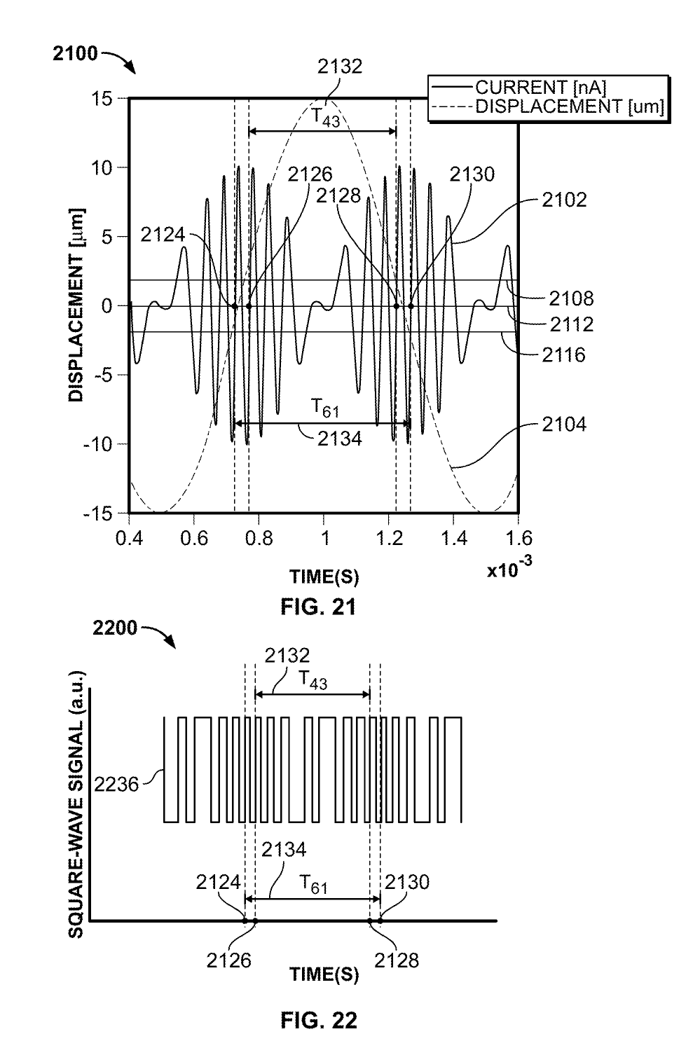

FIG. 21 depicts a graph 2100 that illustrates the response of a current to an oscillator displacement. The graph 2100 includes a current curve 2102 and a displacement curve 2104. The current curve 2102 represents an input signal for a TIA. The TIA may produce an output signal such as one or both of the TIA output curves 1902 and 2002 in response. The current curve 2102 is a capacitive current between the fixed beam 1704 (FIG. 17) and the movable beam 1702 (FIG. 17) in response to displacement of the movable beam 1702 (FIG. 17) according to the displacement curve 2104. The current curve 2102 crosses zero at numerous times, including times 2124, 2126, 2128, and 2130. At the times 2124 and 2130, the movable element 1702 (FIG. 17) has a displacement of −d₀, as shown in the graph 2100. At the times 2126 and 2128, the movable element 1702 (FIG. 17) has a displacement of +d₀, shown on the graph 2100.

The graph 2100 includes two time intervals T₄₃ 2132 and T₆₁2134. The time interval T₄₃ 2132 corresponds to the difference in time between time 2126 and time 2128. The time interval T₆₁ 2134 corresponds to the time difference between times 2124 and 2130. Thus, time interval T₆₁ 2134 corresponds to the time between subsequent crossings of the −d₀ 2116 level, and the time interval T₄₃ 2132 corresponds to the time interval between subsequent crossings of the +d₀ 2108 level. The methods used to determine the time intervals T₄₃ 2132 and T₆₁ 2134 can be used to determine other time intervals, such as between a crossings of the +d₀ 2108 and the next subsequent crossing of the −d₀ 2116 level, between a time interval between a crossing of the −d₀ 2116 level and the next crossing of the +d₀ 2108 level, between the time 2130 and the next crossing of the +d₀ 2108 level, between crossings of the zero 2112 level, between zero-crossings due to a maximum or minimum of displacement, or between any other combination of zero-crossings of the current curve 2702 or a TIA output signal corresponding to the current curve 2102.

FIG. 22 depicts a graph 2200 showing a rectangular waveform signal representing zero-crossing times of the current signal 2102. The graph 2200 includes a rectangular waveform curve 2236. The rectangular waveform curve 2236 has substantially two values: a high value and a low value. While the rectangular waveform curve 2236 may have intermediate values as it transitions between the high and low values, the time spent at intermediate values is far less than the combined time spent at the high and low of the values.

The rectangular waveform curve 2236 can be produced by a variety of methods, including using a comparator to detect changes in an input signal, by amplifying an input signal to the limits of an amplifier so as to saturate the amplifier (amplifying to the rails), by using an analog-to-digital converter, and the like. One way to produce this rectangular waveform curve 2236 from the current curve 2102 is to use a comparator to detect zero-crossings of the current curve 2102. When the current curve 2102 has a value greater than a reference level (such as zero), the comparator outputs a high value, and when the current curve 2102 has a value less than the reference level (such as zero), the comparator has a low value. The comparator's output transitions from low to high when the current curve 2102 transitions from a negative value to a positive value, and the comparator's output transitions from high to low when the current curve 2102 transitions from a positive value to a negative value. Thus, times of rising edges of the rectangular waveform curve 2236 correspond to times of negative-to-positive zero-crossings of the current curve 2104, and falling edges of the rectangular waveform curve 2236 correspond to positive-to-negative zero-crossings of the current curve 2102.

The rectangular waveform curve 2236 includes the same time intervals 2132 and 2134 as the current curve 2102. One benefit of converting the current curve 2102 to a rectangular waveform signal such as the rectangular waveform curve 2236 is that in a rectangular waveform signal, rising and falling edges are steeper. Steep rising and falling edges provide more accurate resolution of the timing of the edges and lower timing uncertainty. Another benefit is that rectangular waveform signals are amenable to digital processing.

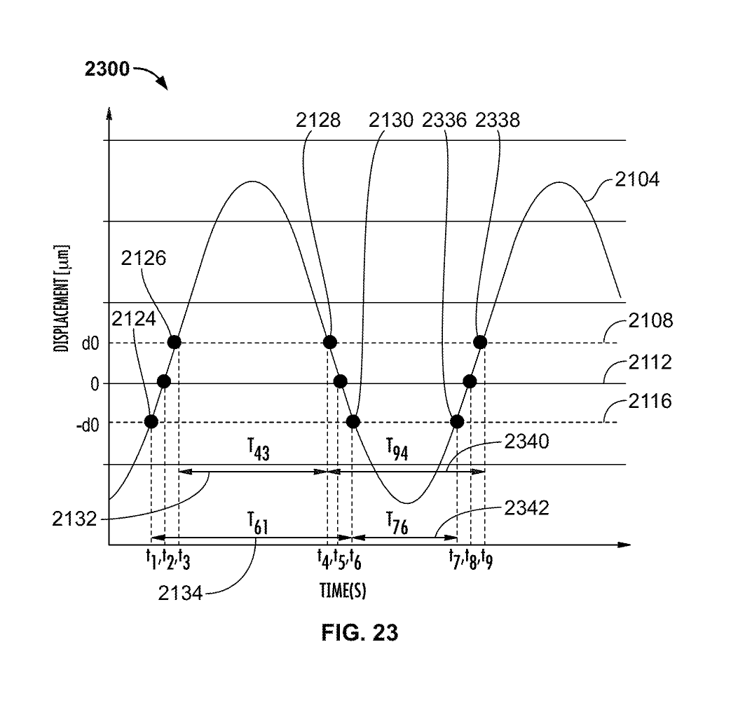

FIG. 23 depicts a graph 2300 which illustrates additional time intervals of displacement curve 2104. In addition to the times depicted in the graph 2100, the graph 2300 includes times 2336 and 2338. In addition to the time intervals depicted in the graph 2100, the graph 2300 includes the time interval T₉₄ 2340 and the time interval T₇₆ 2342. The time interval T₉₄ 2340 corresponds to the time interval between times 2128 and 2338, both crossings of the d₀ 2108 level. The time interval T₇₆ 2342 corresponds to the time interval between times 2130 and 2336, both crossings of the −d₀ 2116 level.

As can be seen in FIG. 19, the oscillator displacement as shown by the displacement curve 1904 experiences an offset that is correlated with input acceleration as indicated by the acceleration curve 1906. Thus, one way to detect shifts of the displacement curve 2104 and thus input acceleration is to compare relative positions of zero-crossing times. For example, a sum of the time intervals T₄₃ 2132 and T₉₄ 2340 represents a period of oscillation as does a sum of the periods T₆₁ 2134 and T₃₆ 2342. In comparing a subset of the period, such as comparing the time interval T₄₃ 2132 with the sum of T₄₃ 2132 and T₉₄ 2340 represents the proportion of time that the oscillator spends at a displacement greater than +d₀ 2108. An increase in this proportion from a reference proportion indicates a greater acceleration in a positive direction than the reference. Likewise, a decrease in this proportion from the reference indicates a greater acceleration in the negative direction. Other time intervals can be used to calculate other proportions and changes in acceleration.

In some examples, integrating portions of the rectangular waveform using the systems and methods described herein can be performed to determine relative positions of zero-crossing times and thus acceleration, rotation and/or velocity. In other examples, displacement of an oscillator can be determined from the time intervals depicted in FIG. 23 using equations 1, 2, and 3.

$$\begin{matrix}d = \frac{2 {d}_{0} cos ( π \frac{{T}_{61}}{{P}_{m 1}} )}{cos ( π \frac{{T}_{61}}{m 1} ) - cos ( π \frac{{T}_{43}}{{P}_{m 2}} )} - {d}_{0} & ( 1 ) \\ {P}_{m 1} = {T}_{61} + {T}_{76} & ( 2 ) \\ {P}_{m 2} = {T}_{43} + {T}_{94} & ( 3 )\end{matrix}$$

Displacement of the oscillator can be converted to an acceleration using Hooke's Law. Displacement of the oscillator can be calculated recursively for each half cycle of the oscillator. Using this information, the displacement of the oscillator can be recorded as a function of time. This allows the calculation of external perturbations with zero drift and lower broadband noise.

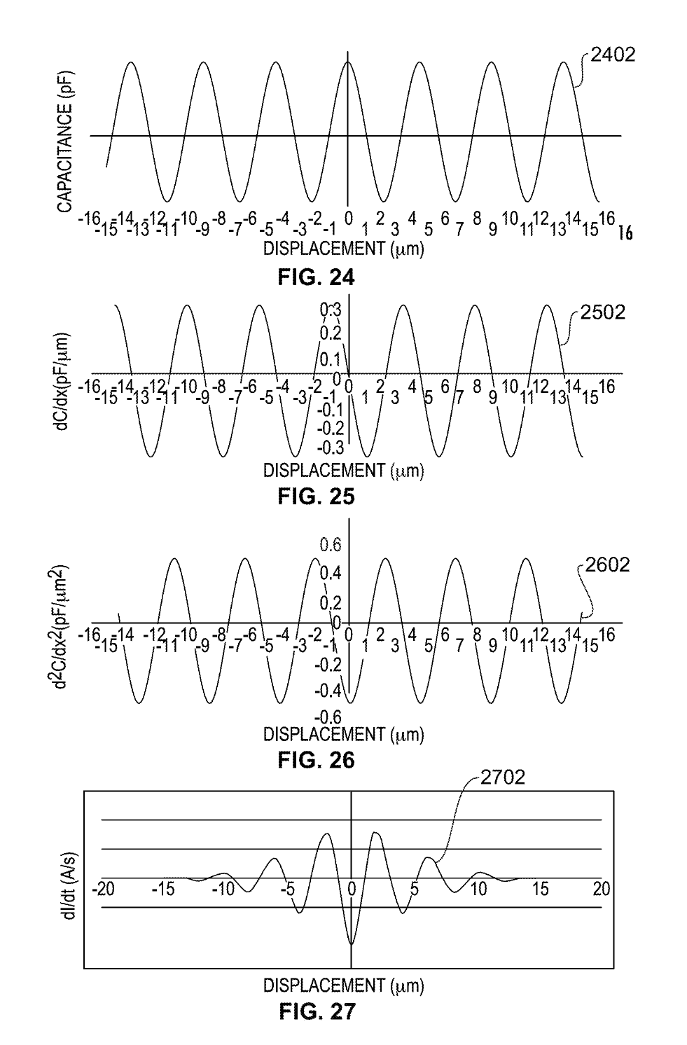

FIG. 24 depicts a relationship between capacitance of an inertial sensor (e.g., the inertial sensor 1800) and displacement of a movable element (e.g., movable element 1702). FIG. 24 includes a capacitance curve 2402 that is periodic and substantially sinusoidal. Thus, monotonic motion of the movable element 1702 (FIG. 17) produces a capacitance that changes non-monotonically with displacement. This non-monotonically is a function of the geometric structure of the sensor 100 and the manner in which the sensor 100 is excited.

FIG. 25 depicts a relationship between displacement and the first derivative of capacitance with respect to displacement. FIG. 25 includes a dC/dx curve 2502 which is periodic and substantially sinusoidal. The dC/dx curve 2502 is the first derivative of the capacitance curve 2402. As such, the dC/dx curve 2502 crosses zero when the capacitance curve 2402 experiences a local extremum. Capacitive current is proportional to the first derivative of capacitance and thus proportional to, and shares zero-crossings with, the dC/dx curve 2502.

FIG. 26 depicts a relationship between displacement and the second derivative of capacitance with respect to displacement. FIG. 26 includes a d²C/dx² curve 2602. The dC/dx² curve 2602 is the first derivative of the dC/dx curve 2502 and as such has a value of zero at local extrema of the dC/dx curve 2502. The d²C/dx² curve 2602 indicates the slope of the dC/dx curve 2502 and thus indicates locations at which the current is most rapidly changing. In some implementations, it is desirable to maximize the amplitude of the d²C/dx curve 2602 to maximize the steepness of the current curve. This reduces uncertainty in resolving timing of zero-crossings of the current. Reducing uncertainty of the zero-crossing times results in decreased system noise and decreased jitter, as well as, lower gain required of the system. Decreased jitter results in improved resolution of external perturbations. In some implementations, it is desirable to minimize the impact of variable parasitic capacitance, which is parasitic capacitance that varies with oscillator motion.

FIG. 27 depicts a relationship between time, the rate of change of capacitive current, and displacement. FIG. 27 includes a dI/dt curve 2702. The capacitive current used to determine the dI/dt curve 2702 is obtained by applying a fixed voltage across the capacitor used to produce the capacitive curve 2402. The dI/dt curve 2702 represents the rate at which the capacitive current is changing with time and thus provides an indicator of the steepness of the current slope. High magnitudes of the dI/dt signal indicate rapidly changing current and high current slopes. Since the oscillator used to generate the curves shown in FIGS. 24-27 oscillates about zero displacement and reverses direction at displacements of +15 μm and −15 μm, the velocity of the oscillator is lowest at its extrema of displacement. At these displacement extrema, the current is also changing less rapidly and thus the dI/dt curve 2702 has a lower magnitude. Using zero-crossings at which the dI/dt curve 2702 has large values results in improved timing resolution and decreased jitter. These zero-crossings occur near the center of the oscillator's range.

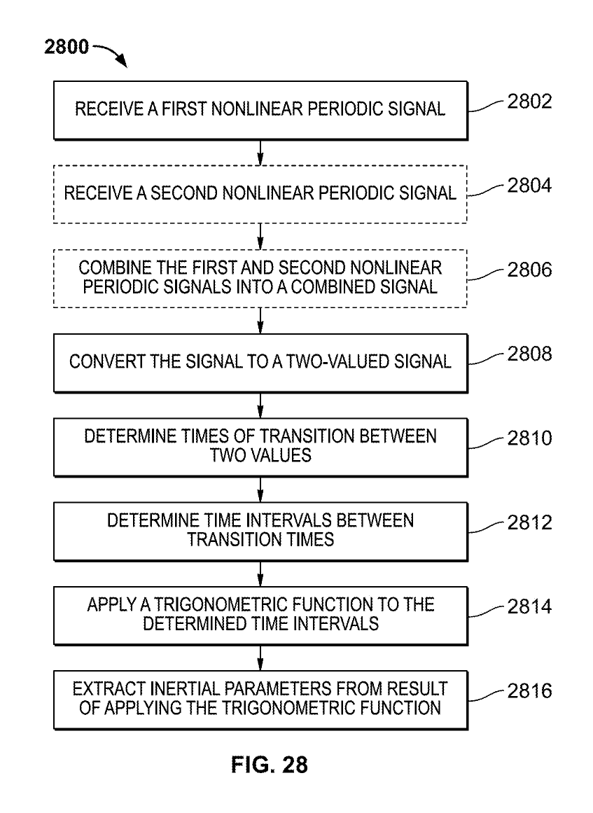

FIG. 28 depicts a flow chart of a method 2800 used to extract inertial parameters from a nonlinear periodic signal. At 2802, a first nonlinear periodic signal is received. At 2804, a second nonlinear periodic signal is optionally received. The first nonlinear periodic signal and the optional second nonlinear periodic signal can be generated by any of the TDS structures depicted in FIGS. 1-16 and received at signal processing circuitry configured to extract an inertial parameter from one or more nonlinear periodic signals.

At 2806, optionally, the first and second nonlinear periodic signals are combined into a combined signal. This can be accomplished by the element 1806. If the steps 2804 and 2806 are omitted, the method 2800 proceeds from 2802 directly to 2808.

At 2808, the signal is converted to a two-valued signal by signal processing circuitry that can include a comparator and/or a high-gain amplifier. The two-valued signal can be a signal that has substantially only two values, but may transition quickly between the two values. This two-valued signal can be a digital signal such as that output from a digital circuit element. In some examples, the two-valued signal is produced by amplifying the combined signal or one of the first and second nonlinear signals using a high-gain amplifier. This technique can be referred to as “amplifying to the rails.” The two-valued signal can be the signal 1812. The two-valued signal can be determined based on a threshold such that if the combined, first, or second signal is above the threshold, the two-valued signal takes on a first value and if below the threshold, the two-valued signal takes on a second value.

At 2810, times of transitions between the two values of the two-valued signal are determined. In some examples, these times can be determined using a time-to-digital converter (TDC) or by an analog to digital converter and digital signal processing. The time intervals determined in this way can be one or more of the intervals 2132, 2134, 2340, and 2342.

At 2814, a trigonometric function is applied to the determined time intervals. The trigonometric function can be a sine function, a cosine function, a tangent function, a cotangent function, a secant function, and a cosecant function. The trigonometric function can also be one or more of the inverse trigonometric functions such as the arcsine, the arccosine, the arctangent, the arccotangent, the arcsecant, and the arccosecant functions. Applying the trigonometric function can include applying a trigonometric function to an argument that is based on the determined time intervals.

At 2816, inertial parameters are extracted from the result of applying the trigonometric function. Extracting the inertial parameters can include curve fitting and computing derivatives of the result. The inertial parameters can be one or more of sensor acceleration, sensor velocity, sensor displacement, sensor rotation rate, sensor rotational acceleration and higher order derivatives of linear or rotational acceleration, such as jerk, snap, crackle, and pop.

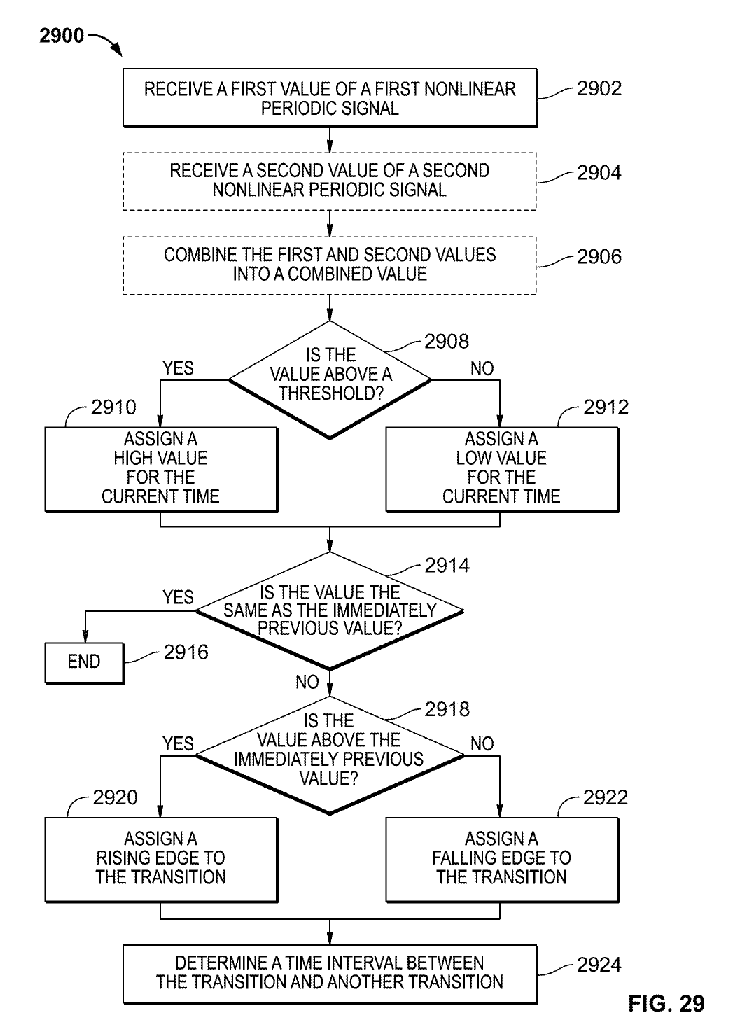

FIG. 29 depicts a method 2900 for determining times of transition between two values based on nonlinear periodic signals. The method 2900 can be used to perform one or more of the steps 2802, 2804, 2806, 2808, and 2810 of the method 2800.

At 2902, a first value of a first nonlinear periodic signal is received at signal processing circuitry that can include a TDC or digital circuitry. At 2904, a second value of a second nonlinear periodic signal is optionally received at the TDC or digital circuitry. The first and second values are values of the first and second signals at particular moments in time, and can be analog or digital values. The first and second nonlinear periodic signals of the method 2900 can be the same as the first and second nonlinear periodic signals of the method 2800.

At 2906, the first and second values are optionally combined into a combined value. The values may be combined using the element 1806, which may include a summing amplifier, a differential amplifier, an analog multiplier, and/or an analog divider. Combining may include summing the values, taking a difference of the values, multiplying the values, or dividing the values. If the optional steps 2904 and 2906 are omitted, the method 2900 proceeds from 2902 directly to 2908.

At 2908, the first value or the combined value is compared to a threshold. If the value is above the threshold, the method 2900 proceeds to 2910.

At 2910, a high value is assigned for the current time. If the value is not above the threshold, the method 2900 proceeds to 2912. At 2912, a low value is assigned for the current time. The steps 2908, 2910 and 2912 can be used to generate a two-valued signal having high and low values from an input signal. The two-valued signal of the method 2900 can be the same as the signal of the method 2800.

At 2914, the value of the signal for the current time is compared to a value of the signal for an immediately previous time. If the two values are the same, the method 2900 proceeds to 2916 where the method 2900 terminates. If the two values are not the same, a transition has occurred and the method proceeds to 2918.

At 2918, the sense of the transition (whether the transition is a rising edge or a falling edge) is determined. If the value for the current time is greater than the value for the previous time, a rising edge is assigned to the transition.

If the value for the current time is not above the value for the previous time, the method 2900 proceeds to 2922. At 2922, a falling edge is assigned to the transition. Thus, times having transitions are detected and classified as having either rising or falling edges. At 2924, a time interval is determined between the transition and another transition. Time intervals between these transition times can be determined by obtaining a difference in time values between times of transition.

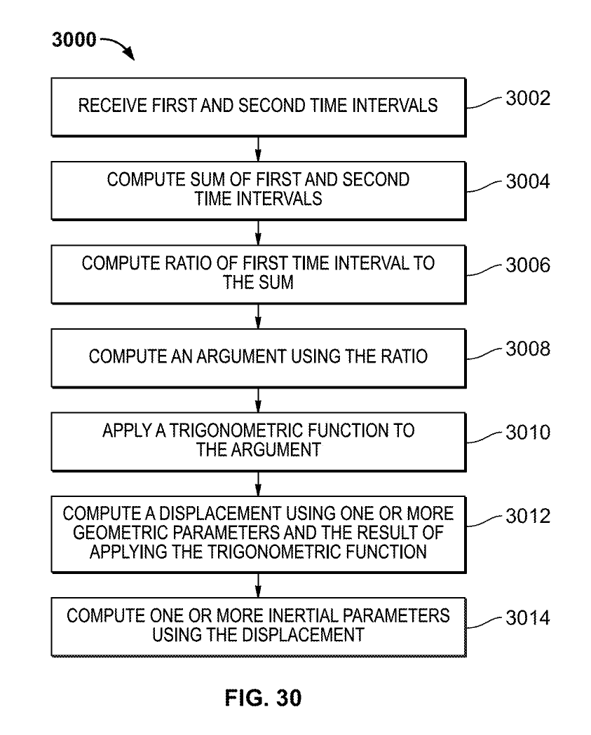

FIG. 30 depicts a method 3000 to compute inertial parameters from time intervals. The method 3000 can be used to perform one or more of the steps 2814 and 2816 of the method 2800.

At 3002, first and second time intervals are received at signal processing circuitry that can include a TDC or digital circuitry. The first and second time intervals can be determined using the method 2900.

At 3004, a sum of the first and second time intervals is computed using digital signal processing circuitry such as an application specific integrated circuit (ASIC) or a field programmable gate array (FPGA). The sum can be the measured period as described by equations 2 and 3. At 3006, a ratio of the first time interval to the sum is computed. The ratio can be one or more of the ratios forming part of the arguments of the cosine functions in equation 1.

At 3008, an argument is computed using the ratio by the digital signal processing circuitry. The argument can be one or more of the arguments of the cosine functions of equation 1.

At 3010, a trigonometric function is applied to the argument by the digital signal processing circuitry. The trigonometric function can be any of the trigonometric functions described with reference to step 2904 of the method 2900.

At 3012, the digital signal processing circuitry computes a displacement using one or more geometric parameters and using the result of applying the trigonometric function. The displacement can be computed using equation 1. Computing displacement can involve computing more than one trigonometric function, and arguments other than the computed argument of 2008 can be included as arguments of some of the trigonometric functions.

At 3014, the digital signal processing circuitry computes one or more inertial parameters using the displacement. The inertial parameters computed can be any of the inertial parameters described with reference to step 2816 of the method 2800. Inertial parameters can be computed by obtaining one or more derivatives of the displacement with respect to time. Inertial parameters may be extracted using an offset of the computed displacement to determine an external acceleration. In this way, inertial parameters are computed from time intervals.

The systems described herein can be fabricated using MEMS and microelectronics fabrication processes such as lithography, deposition, and etching. The features of the MEMS structure are patterned with lithography and selected portions are removed through etching. Such etching can include deep reactive ion etching (DRIE) and wet etching. In some examples, one or more intermediate metal, semiconducting, and/or insulating layers are deposited. The base wafer can be a doped semiconductor such as silicon. In some examples, ion implantation can be used to increase doping levels in regions defined by lithography. The spring systems can be defined in a substrate silicon wafer, which is then bonded to top and bottom cap wafers, also made of silicon. Encasing the spring systems in this manner allows the volume surrounding the mass to be evacuated. In some examples, a getter material such as titanium is deposited within the evacuated volume to maintain a low pressure throughout the lifetime of the device. This low pressure enhances the quality factor of the resonator. From the MEMS structure, conducting traces are deposited using metal deposition techniques such as sputtering or physical vapor deposition (PVD). These conducting traces electrically connect active areas of the MEMS structure to microelectronic circuits. Similar conducting traces can be used to electrically connect the microelectronic circuits to each other. The fabricated MEMS and microelectronic structures can be packaged using semiconductor packaging techniques including wire bonding and flip-chip packaging.

As used herein, the term “memory” includes any type of integrated circuit or other storage device adapted for storing digital data including, without limitation, ROM, PROM, EEPROM, DRAM, SDRAM, DDR/2 SDRAM, EDO/FPMS, RLDRAM, SRAM, flash memory (e.g., AND/NOR, NAND), memrister memory, and PSRAM.

As used herein, the term “processor” is meant generally to include all types of digital processing devices including, without limitation, digital signal processors (DSPs), reduced instruction set computers (RISC), general-purpose (CISC) processors, microprocessors, gate arrays (e.g., FPGAs), PLDs, reconfigurable compute fabrics (RCFs), array processors, secure microprocessors, and ASICs). Such digital processors may be contained on a single unitary integrated circuit die, or distributed across multiple components.

From the above description of the system it is manifest that various techniques may be used for implementing the concepts of the system without departing from its scope. In some examples, any of the circuits described herein may be implemented as a printed circuit with no moving parts. Further, various features of the system may be implemented as software routines or instructions to be executed on a processing device (e.g. a general purpose processor, an ASIC, an FPGA, etc.) The described embodiments are to be considered in all respects as illustrative and not restrictive. It should also be understood that the system is not limited to the particular examples described herein, but can be implemented in other examples without departing from the scope of the claims.

Similarly, while operations are depicted in the drawings in a particular order, this should not be understood as requiring that such operations be performed in the particular order shown or in sequential order, or that all illustrated operations be performed, to achieve desirable results.

References to axes as x, y, z, u, v, major, and/or minor axes are for the purpose of distinguishing between different axes. A different notation for any given axis, or different axis orientations, can be used without affecting the scope of the disclosure.

The terms first, second, third, fourth, fifth, sixth, seventh, eighth, ninth, etc. are used herein to distinguish between elements, components, etc. These terms when used herein do not imply a sequence or order unless clearly indicated by the context.

What is claimed is:

1. A system comprising:
a proof mass;
a rotational drive configured to rotate about a z axis;
a first structure connecting the rotational drive to the proof mass and comprising:
a major axis that passes from a first anchor to the proof mass and is aligned with a y axis when the first structure is at rest, the y axis perpendicular to the z axis, and
a coupling spring with a stiffness along a minor axis perpendicular to the major axis that is different than a stiffness along the major axis;
a second structure comprising a drive spring with a stiffness along the y axis that is different than a stiffness along an x axis perpendicular to the y and z axes; and
a second anchor connected to the proof mass by the second structure.

2. The system of claim 1, wherein the coupling spring and the drive spring are configured to cause the proof mass to move substantially along the x axis when the rotational drive rotates about the z axis.

3. The system of claim 1, wherein the coupling spring is configured to bend when the rotational drive rotates.

4. The system of claim 1, wherein:
a center of mass of the proof mass is radially between a point at which the drive spring is attached to the proof mass and a point at which the coupling spring is attached to the proof mass.

5. The system of claim 4, wherein the drive spring exerts, on the proof mass, a torque that substantially prevents rotation of the proof mass about the center of mass.

6. The system of claim 1, wherein:
the first structure comprises an arm;
the stiffness of the coupling spring along the minor axis is substantially greater than the stiffness of the coupling spring along the major axis; and
the stiffness of the drive spring along the y axis is substantially greater than the stiffness of the drive spring along the x axis.

7. The system of claim 1, further comprising:
a second drive spring connected to the proof mass and a third anchor, the second drive spring with a stiffness along the y axis that is different than a stiffness along an x axis.

8. The system of claim 1, wherein the drive spring is configured to:
expand when the rotational drive rotates about the z axis with a first rotation vector; and
compress when the rotational drive rotates about the z axis with a second rotation vector opposite to the first rotation vector.

9. The system of claim 1, wherein:
the first structure comprises a drive frame;
the stiffness of the coupling spring along the major axis is substantially greater than the stiffness of the coupling spring along the minor axis;
the stiffness of the drive spring along the y axis is substantially greater than the stiffness of the drive spring along the x axis.

10. The system of claim 1, the proof mass further comprising a sensor configured to characterize the motion of the proof mass along the x axis.

11. The system of claim 10, the sensor comprising a comb.

12. The system of claim 10, the sensor comprising a time-domain-switched structure.

13. The system of claim 10, the sensor configured to determine an acceleration of the system along the x axis.

14. The system of claim 10, the sensor configured to determine a velocity of the proof mass along the x axis.

15. The system of claim 1, further comprising:
a second proof mass connected to the rotational drive by a third structure comprising a second coupling spring; and
a third anchor connected to the second proof mass by a fourth structure comprising a second drive spring;
wherein the second coupling spring and the second drive spring are configured to cause the second proof mass to move substantially along the y axis when the rotational drive rotates about the z axis.

16. The system of claim 6, wherein the coupling spring comprises:
a first coupling joint connected to an end of the arm;
first and second flex arms connected to the first coupling joint;
first and second forks connected to the first and second flex arms, respectively;
third and fourth flex arms connected to the first and second forks, respectively; and
a second coupling joint connected to the third and fourth flex arms and to the proof mass.

17. The system of claim 6, wherein the drive spring comprises:
an anchor fork connected to the second anchor;
an anchor arm connected to the anchor fork;
a first drive fork connected to the anchor arm;
a drive arm connected to the first drive fork; and
a second drive fork connected to the drive arm and to the proof mass.

18. The system of claim 7, wherein the second drive spring comprises:
a second anchor fork connected to the third anchor;
a second anchor arm connected to the second anchor fork;
a third drive fork connected to the second anchor arm;
a second drive arm connected to the third drive fork; and
a fourth drive fork connected to the second drive arm and to the proof mass.

19. The system of claim 9, wherein the coupling spring comprises:
a driving fork connected to the drive frame;
first and second driving arms connected to the driving fork;
first and second middle forks connected to the first and second driving arms, respectively;
first and second middle arms connected to the first and second middle forks, respectively;
a first driven fork connected to the first and second middle arms;
a driven arm connected to the first driven fork; and
a second driven fork connected to the driven arm and to the proof mass.

20. The system of claim 9, wherein the coupling spring comprises:
a first coupling joint connected to the drive frame;
first and second flex arms connected to the first coupling joint;
first and second forks connected to the first and second flex arms, respectively;
third and fourth flex arms connected to the first and second forks, respectively; and
a second coupling joint connected to the third and fourth flex arms and to the proof mass.

21. The system of claim 9, wherein the drive spring comprises:
an anchor fork connected to the second anchor;
an anchor arm connected to the anchor fork;
a first drive fork connected to the anchor arm;
a drive arm connected to the first drive fork; and
a second drive fork connected to the drive arm and to the proof mass.

22. The system of claim 1, further comprising:
a second proof mass connected to the rotational drive by a third structure comprising a second coupling spring; and
a third anchor connected to the second proof mass by a fourth structure comprising a second drive spring;
wherein the second coupling spring and the second drive spring are configured to cause the second proof mass to move substantially along the third axis when the rotational drive rotates about the second axis.

23. The system of claim 22, further comprising:
a third proof mass connected to the rotational drive by a fifth structure comprising a third coupling spring; and
a fourth anchor connected to the third proof mass by a sixth structure comprising a third drive spring;
wherein the third coupling spring and the third drive spring are configured to cause the third proof mass to move substantially along the first axis when the rotational drive rotates about the second axis.

24. The system of claim 23, further comprising:
a fourth proof mass connected to the rotational drive by a seventh structure comprising a fourth coupling spring; and
a fifth anchor connected to the fourth proof mass by an eighth structure comprising a fourth drive spring;
wherein the fourth coupling spring and the fourth drive spring are configured to cause the fourth proof mass to move substantially along the third axis when the rotational drive rotates about the second axis.

25. The system of claim 24, further comprising:
a fifth proof mass connected to the rotational drive by a ninth structure comprising a fifth coupling spring; and
a sixth anchor connected to the fifth proof mass by a tenth structure comprising a fifth drive spring;
wherein the fifth coupling spring and the fifth drive spring are configured to cause the fifth proof mass to move substantially along a fourth axis when the rotational drive rotates about the second axis, the fourth axis perpendicular to the second axis.

26. The system of claim 25, further comprising:
a sixth proof mass connected to the rotational drive by a eleventh structure comprising a sixth coupling spring; and
a seventh anchor connected to the sixth proof mass by a twelfth structure comprising a sixth drive spring;
wherein the sixth coupling spring and the sixth drive spring are configured to cause the sixth proof mass to move substantially along the fourth axis when the rotational drive rotates about the second axis.

27. The system of claim 26, further comprising:
a seventh proof mass connected to the rotational drive by a thirteenth structure comprising a seventh coupling spring;
a eighth anchor connected to the seventh proof mass by a fourteenth structure comprising a seventh drive spring;
an eighth proof mass connected to the rotational drive by a fifteenth structure comprising an eighth coupling spring; and
a ninth anchor connected to the eighth proof mass by a sixteenth structure comprising an eighth drive spring;
wherein:
the seventh coupling spring and the seventh drive spring are configured to cause the seventh proof mass to move substantially along a fifth axis when the rotational drive rotates about the second axis, the fifth axis perpendicular to the second and fourth axes, and
the eighth coupling spring and the eighth drive spring are configured to cause the eighth proof mass to move substantially along the fifth axis when the rotational drive rotates about the second axis.
